(19) United States
(12) Patent Application Publication
(10) Pub. No.: US 2024/0363663 A1
(43) Pub. Date: Oct. 31, 2024

(54) SENSOR DEVICE AND MANUFACTURING METHOD

(71) Applicant: SONY SEMICONDUCTOR SOLUTIONS CORPORATION, KANAGAWA (JP)

(72) Inventors: SHINGO TAKAHASHI, KANAGAWA (JP); YOSHIYUKI OHBA, KUMAMOTO (JP); SHINJI MIYAZAWA, KANAGAWA (JP); HIROSHI ISOBE, KANAGAWA (JP); TAKUYA ITO, KANAGAWA (JP); YASUFUMI MIYOSHI, KANAGAWA (JP); MICHIHIRO NAKANO, KUMAMOTO (JP)

(21) Appl. No.: 18/556,417

(22) PCT Filed: Apr. 15, 2022
(86) PCT No.: PCT/JP2022/017932

§ 371 Date: Oct. 20, 2023

(30) Foreign Application Priority Data
May 7, 2021 (JP) 2021-079301

(51) Int. Cl. H01L 27/146

(52) U.S. Cl. CPC H01L 27/1463; H01L 27/14645; H01L 27/14683

(57) ABSTRACT

A sensor device according to the present technology includes a semiconductor substrate that includes a plurality of photoelectric conversion elements arranged for each pixel and a pixel separation portion having a trench formed between pixels to separate the pixels. The pixel separation portion of the semiconductor substrate is formed in directions different from cleavage directions of crystals of the semiconductor substrate.

### TECHNICAL FIELD

The present technology relates to a sensor device and a manufacturing method of this sensor device, and particularly to a sensor device having a semiconductor substrate which includes a plurality of photoelectric conversion elements arranged for each pixel and a pixel separation portion that has a trench formed between pixels and that separates the pixels, and to a manufacturing method of this sensor device.

### BACKGROUND ART

There is widely known a sensor device which has an array of a plurality of pixels each including a photoelectric conversion element, such as a CCD (Charge Coupled Device) image sensor and a CMOS (Complementary Metal Oxide Semiconductor) image sensor.

A sensor device known as this type includes a pixel separation portion having a trench formed between pixels to separate the pixels. A film including a light absorbing material or a light reflecting material can be formed in the trench. This configuration is expected to reduce leakage of light between the pixels.

Note that pieces of patent literature listed below are conventional technologies related to the present technology.

### CITATION LIST

### Patent Literature

### [PTL 1]

Japanese Patent Laid-Open No. 2009-65118

### [PTL 2]

Japanese Patent Laid-Open No. 2019-161224

### [PTL 3]

Japanese Patent Laid-Open No. 2006-59842

### [PTL 4]

Japanese Patent Laid-Open No. 2007-27392

### SUMMARY

### Technical Problem

Here, for achieving a manufacturing process of the sensor device of this type, heat treatment such as annealing is performed for the semiconductor substrate which has the pixel separation portion having the trench described above. This heat treatment causes a heat shrink of the semiconductor substrate, and may generate a crack from a vicinity of the trench according to the heat shrink.

The present technology has been developed in consideration of the above-mentioned circumstances. An object of the present technology is to provide a sensor device that includes a semiconductor substrate which has a pixel separation portion having a trench for separation of pixels and that is capable of achieving prevention of crack generation of the semiconductor substrate.

### Solution to Problem

A first sensor device according to the present technology includes a semiconductor substrate that includes a plurality of photoelectric conversion elements arranged for each pixel and a pixel separation portion having a trench formed between pixels to separate the pixels. The pixel separation portion of the semiconductor substrate is formed in directions different from cleavage directions of crystals of the semiconductor substrate.

The pixel separation portion formed in directions different from the cleavage directions as described above prevents easy crack generation in the semiconductor substrate along the trench of the pixel separation portion.

A second sensor device according to the present technology includes a semiconductor substrate that includes a plurality of photoelectric conversion elements arranged for each pixel and a pixel separation portion having a trench formed between pixels to separate the pixels, a first insulation film formed on a first surface that is one of two surfaces crossing a thickness direction of the semiconductor substrate at right angles and that corresponds to a surface where the trench is engraved and on an outermost peripheral portion of the trench, and a second insulation film formed on the first insulation film. The first insulation film is formed such that the trench has an opening on a first surface side. The second insulation film is formed across an upper part of the opening of the trench.

The configuration which includes the first insulation film formed such that the trench has the opening on the first surface side as described above prevents contact between portions of the first insulation film in the trench in a sensor device manufacturing process.

In addition, a manufacturing method of the second sensor device according to the present technology includes a first film forming step of forming a first insulation film on a first surface that is one of two surfaces crossing a thickness direction of a semiconductor substrate at right angles and that corresponds to a surface where a vertical groove is engraved and on a side wall portion of the vertical groove, the semiconductor substrate being a substrate where a plurality of photoelectric conversion elements is arranged for each pixel and including the vertical groove separating the pixels, and a second film forming step of forming a second insulation film on the first insulation film. The first film forming step forms the first insulation film such that the vertical groove has an opening on a first surface side. The second film forming step forms the second insulation film across an upper part of the opening of the vertical groove.

This method prevents contact between portions of the first insulation film formed on the side wall portion of the vertical groove for pixel separation, in the sensor device manufacturing process.

A third sensor device according to the present technology includes a semiconductor substrate that includes a plurality of photoelectric conversion elements arranged for each pixel and a pixel separation portion having a trench formed between pixels to separate the pixels. An insulation film is formed at an outermost peripheral portion of the trench. A metal film is formed inside the insulation film. A similar heat expansion material that has a heat expansion characteristic similar to a heat expansion characteristic of a material constituting the semiconductor substrate is embedded inside the metal film.

As described above, the similar heat expansion material for the material constituting the semiconductor substrate is embedded inside the metal film in the trench. Accordingly, even if a heat shrink is caused by heat treatment during manufacture of the sensor device, the degrees of the heat shrink outside the trench and inside the trench are equalized. This configuration can reduce stress produced at an entrance portion of the trench according to the heat treatment described above.

A fourth sensor device according to the present technology includes a semiconductor substrate that includes a plurality of photoelectric conversion elements arranged for each pixel and a pixel separation portion having a trench formed between pixels to separate the pixels, an insulation film formed on a first surface that is one of two surfaces crossing a thickness direction of the semiconductor substrate at right angles and that corresponds to a surface where the trench is engraved and on an outermost peripheral portion of the trench, a wetting film formed on the insulation film, and a metal film formed on the wetting film. The wetting film becomes amorphous or microcrystalline on the insulation film in the trench and has highly oriented crystals on the insulation film outside the trench.

In the state where the wetting film for forming the metal film in the trench is amorphous or microcrystalline on the insulation film in the trench as described above, easy generation of voids in the metal film in the trench is avoidable.

### BRIEF DESCRIPTION OF DRAWINGS

FIG. 1 is a block diagram depicting a circuit configuration example of a sensor device according to a first embodiment of the present technology.

FIG. 2 is an equivalent circuit diagram of a pixel included in the sensor device according to the embodiment.

FIG. 3 is a cross-sectional diagram for explaining a schematic structure of a pixel array unit according to the first embodiment.

FIG. 4 is a plan diagram for explaining schematic structures of a pixel separation structure and a pixel light shielding structure according to the embodiment.

FIG. 5 is an explanatory diagram of a crack.

FIG. 6 is an explanatory diagram of an example of forming directions of a pixel separation portion of the first embodiment.

FIG. 7 is an explanatory diagram of another example of forming directions of a pixel separation portion of the first embodiment.

FIG. 8 is an explanatory diagram of a crack generated from an outermost peripheral portion of a pixel arrangement region.

FIG. 9 depicts explanatory diagrams of a chamfered shape.

FIG. 10 is a diagram depicting an example of a metal film covering an upper part of a trench formed along outermost peripheral sides of the pixel arrangement region.

FIG. 11 is an explanatory diagram of a modification of the metal film.

FIG. 12 is a cross-sectional diagram for explaining a schematic structure of a pixel array unit according to a second embodiment.

FIG. 13 is an explanatory diagram of an example of forming an insulation film in such a manner as to close an entrance portion of the trench with the insulation film.

FIG. 14 is an explanatory diagram of stress causing crack generation.

FIG. 15 is a diagram schematically depicting, in a plan view, a state of a non-cross portion closed by a first insulation film and a cross portion not closed in a film forming step of the first insulation film.

FIG. 16 is a cross-sectional diagram for explaining a principle of formation of a film quality deteriorated portion.

FIG. 17 is an explanatory diagram of a method which does not form a vertical groove at the cross portion and a method which equalizes a width of a vertical groove at the cross portion and a width of a vertical groove at the non-cross portion.

FIG. 18 is an explanatory diagram depicting a manufacturing method of a sensor device according to the second embodiment.

FIG. 19 is a diagram for explaining another example of an insulation film forming method according to the second embodiment.

FIG. 20 is a cross-sectional diagram for explaining a schematic structure of a pixel array unit according to a third embodiment.

FIG. 21 is an explanatory diagram depicting a manufacturing method of a sensor device according to the third embodiment.

FIG. 22 is a diagram illustrating reflectance characteristics for wavelengths of Al, Ag, and Mg and for each film thickness.

FIG. 23 is a diagram illustrating reflectance characteristics for wavelengths of W, Ti, Si, Pd, Ni, Cr, Au, Fe, and Pt as a reference.

FIG. 24 is an explanatory diagram depicting an effect offered in a case where liquid silicon is used as a similar heat expansion material.

FIG. 25 is an explanatory diagram depicting another example of the manufacturing method of the sensor device according to the third embodiment.

FIG. 26 is an explanatory diagram depicting still another example of the manufacturing method of the sensor device according to the third embodiment.

FIG. 27 is a cross-sectional diagram for explaining a schematic structure of a pixel array unit according to a fourth embodiment.

FIG. 28 is an explanatory diagram depicting a manufacturing method of a sensor device according to the fourth embodiment.

FIG. 29 is a diagram for explaining a difference in film formation mode of a metal film between a case where a barrier metal film is present and a case where the barrier metal film is absent.

### DESCRIPTION OF EMBODIMENTS

Embodiments according to the present technology will hereinafter be described in the following order with reference to the accompanying drawings.
<1. First embodiment>
(1-1. Circuit configuration of sensor device)
(1-2. Circuit configuration of pixel)
(1-3. Structure example of pixel array unit)
(1-4. Structure of pixel array unit of first embodiment)
<2. Second Embodiment>
<3. Third Embodiment>
<4. Fourth Embodiment>
<5. Modification>
<6. Summary of embodiments>
<7. Present technology>

### 1. First Embodiment

### (1-1. Circuit Configuration of Sensor Device)

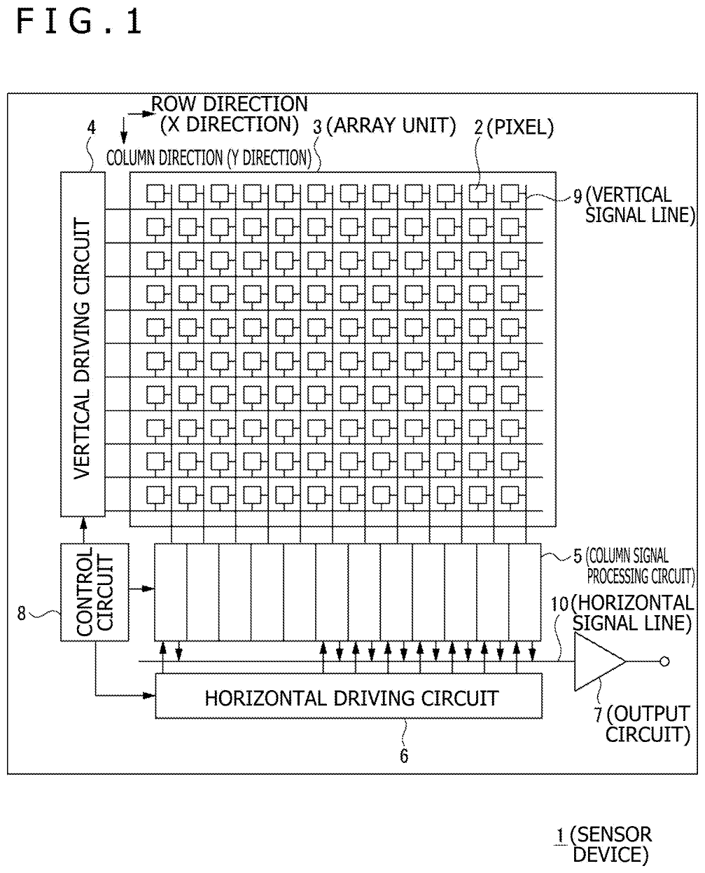

FIG. 1 is a block diagram depicting a circuit configuration example of a sensor device 1 according to a first embodiment of the present technology.

The sensor device 1 of the present embodiment includes a pixel array unit 3 where a plurality of pixels 2 is arranged, a vertical driving circuit 4, column signal processing circuits 5, a horizontal driving circuit 6, an output circuit 7, a control circuit 8, and others.

Each of the pixels 2 includes a photoelectric conversion element and a plurality of pixel transistors. Note that a circuit configuration of the pixels 2 will be again described below.

The pixel array unit 3 includes a plurality of the pixels 2 arranged in each of a row direction and a column direction. In the following description, a row direction will also be referred to as an “X direction,” and a column direction will also be referred to as a “Y direction.”

The pixel array unit 3 includes an effective pixel region which actually receives light, amplifies signal charge generated by photoelectric conversion of the light, and reads and outputs the amplified signal charge to the column signal processing circuits 5. The pixel array unit 3 also includes a black reference pixel region (not depicted) for outputting optical black which is a reference of a black level. The black reference pixel region is generally formed in an outer peripheral portion of the effective pixel region.

The control circuit 8 generates operation clocks, control signals, and the like for the vertical driving circuit 4, the column signal processing circuits 5, and the horizontal driving circuit 6 on the basis of vertical synchronized signals, horizontal synchronized signals, and master clocks, and outputs the generated operation clocks, control signals, and the like to the vertical driving circuit 4, the column signal processing circuits 5, and the horizontal driving circuit 6.

The vertical driving circuit 4 includes a shift register, for example, and selectively scans each of the pixels 2 of the pixel array unit 3 sequentially in the vertical direction for each row. Thereafter, the vertical driving circuit 4 causes the corresponding column signal processing circuit 5 to output, via a vertical signal line 9, a pixel signal corresponding to signal charge obtained according to a quantity of light received by each of the pixels 2.

For example, the column signal processing circuit 5 is disposed for each column of the pixels 2, and perform signal processing, such as noise removal and signal amplification, for signals output from one row of the pixels 2 for each pixel column on the basis of a signal received from the black reference pixel region (not depicted, and formed around the effective pixel region). A horizontal selection switch (not depicted) is provided between a horizontal signal line 10 and an output stage of each of the column signal processing circuits 5.

The horizontal driving circuit 6 includes a shift register, for example, and sequentially outputs a horizontal scanning pulse to sequentially select the column signal processing circuits 5 and cause each of the column signal processing circuits 5 to output a pixel signal to the horizontal signal line 10.

The output circuit 7 performs signal processing for signals sequentially supplied from the respective column signal processing circuits 5 via the horizontal signal line 10, and outputs the processed signals.

### (1-2. Circuit Configuration of Pixel)

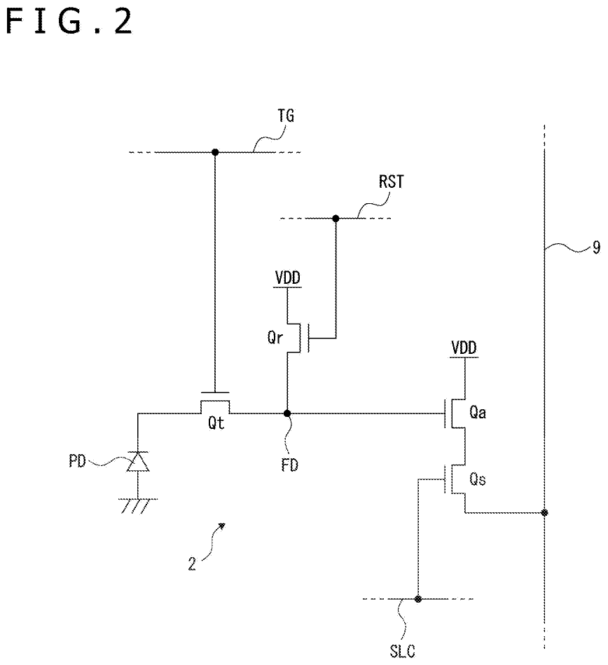

FIG. 2 is an equivalent circuit diagram of the pixel 2.

As depicted in the figure, the pixel 2 includes a photodiode PD as a photoelectric conversion element, and further includes a transfer transistor Qt, a floating diffusion (floating diffusion region) FD, a reset transistor Qr, an amplification transistor Qa, and a selection transistor Qs.

In the present example herein, each of the various types of transistors included in the pixel 2 includes an MOSFET (metal-oxide-semiconductor field-effect transistor), for example.

A gate of the transfer transistor Qt is connected to a supply line of a transfer driving signal TG. When the transfer driving signal TG is turned on, the transfer transistor Qt comes into a conductive state, and transfers signal charge stored in the photodiode PD to the floating diffusion FD.

The floating diffusion FD is a charge retaining unit which temporarily retains charge transferred from the photodiode PD.

A gate of the reset transistor Qr is connected to a supply line of a reset signal RST. When the reset signal RST is turned on, the reset transistor Qr comes into a conductive state, and resets potential of the floating diffusion FD to reference potential VDD.

A source of the amplification transistor Qa is connected to the vertical signal line 9 via the selection transistor Qs, and a drain of the amplification transistor Qa is connected to the reference potential VDD (constant-current source) to constitute a source follower circuit.

The selection transistor Qs is connected between the source of the amplification transistor Qa and the vertical signal line 9, and a gate of the selection transistor Qs is connected to a supply line of a selection signal SLC. When the selection signal SLC is turned on, the selection transistor Qs comes into a conductive state, and outputs charge retained in the floating diffusion FD to the vertical signal line 9 via the amplification transistor Qa.

The transfer drive signal TG, the reset signal RST, and the selection signal SLC herein are output from the vertical driving circuit 4 depicted in FIG. 1.

Operations of the pixel 2 having the foregoing configuration will be briefly explained. Before a start of light reception, a charge reset operation (electronic shutter operation) is first performed to reset charge of the pixel 2. Specifically, the reset transistor Qr and the transfer transistor Qt are turned on (brought into the conductive state), and charge stored in the photodiode PD and the floating diffusion FD is reset.

After the reset of the stored charge, the reset transistor Qr and the transfer transistor Qt are turned off to start storing of charge in the photodiode PD. Thereafter, for reading charge signals stored in the photodiode PD, the transfer transistor Qt is turned on, and the selection transistor Qs is turned on. In this manner, the charge signals are transferred from the photodiode PD to the floating diffusion FD, and the charge signals retained in the floating diffusion FD are output to the vertical signal line 9 via the amplification transistor Qa.

### (1-3. Structure Example of Pixel Array Unit)

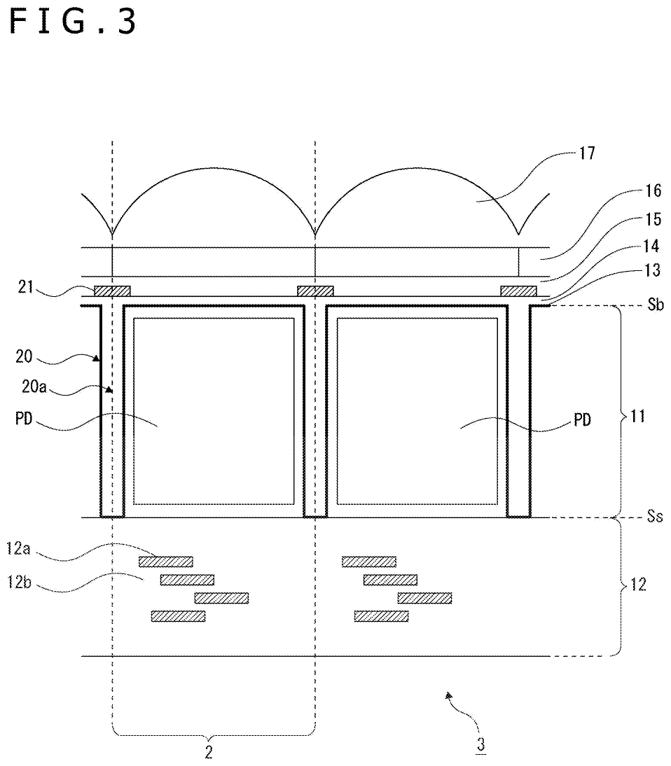

FIG. 3 is a cross-sectional diagram for explaining a schematic structure of the pixel array unit 3.

The sensor device 1 according to the present embodiment constitutes a back-illuminated CMOS (Complementary Metal Oxide Semiconductor) type image sensor. The term “back” in this case is defined with respect to a front surface Ss and a back surface Sb of a semiconductor substrate 11 included in the pixel array unit 3.

As depicted in FIG. 3, the pixel array unit 3 includes the semiconductor substrate 11 and a wiring layer 12 formed on the front surface Ss side of the semiconductor substrate 11. According to the present example, a fixed charge film 13, which is an insulation film having fixed charge, is formed on the back surface Sb of the semiconductor substrate 11, and an insulation film 14 is formed on the fixed charge film 13. Moreover, a pixel light shielding portion 21, a flattening film 15, a filter layer 16, and micro-lenses (on-chip lenses) 17 are stacked in this order on the insulation film 14.

Note that the pixel transistors (the transfer transistor Qt, the reset transistor Qr, the amplification transistor Qa, and the selection transistor Qs) described above are also formed in each of the pixels 2, but those pixel transistors are not depicted in FIG. 3. Conductors functioning as electrodes (respective electrodes of gates, drains, and sources) of the pixel transistors herein are formed in the wiring layer 12 near the front surface Ss of the semiconductor substrate 11.

The semiconductor substrate 11 includes silicon (Si), for example, and has a thickness approximately in a range of 1 to 6 μm, for example. The photodiode PD as a photoelectric conversion element is formed in the semiconductor substrate 11 in each region of the pixels 2. Each of the adjoining photodiodes PD is electrically separated by a pixel separation portion 20.

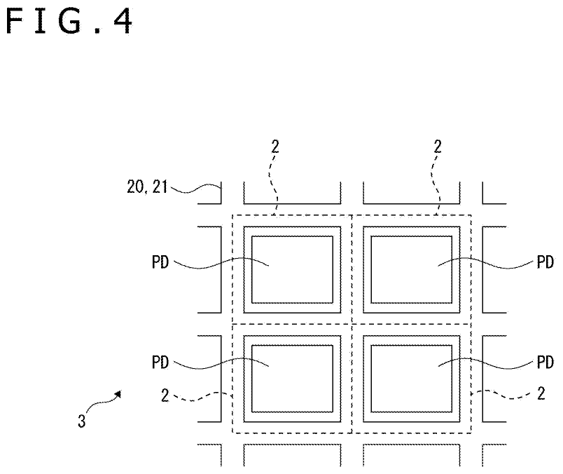

According to the present example, the pixel separation portion 20 is constituted by a part of the fixed charge film 13 and a part of the insulation film 14. As depicted in a plan diagram of FIG. 4 by way of example, the pixel separation portion 20 has a grid shape surrounding the photodiodes PD of the respective pixels 2. The pixel separation portion 20 thus configured has a function of reducing leakage of light between the pixels 2. Moreover, the pixel separation portion 20 also has a function of electrically separating the pixels 2 to prevent leakage of signal charge between the pixels 2.

The pixel separation portion 20 herein can be produced by forming the fixed charge film 13 and the insulation film 14 in a vertical groove formed in such a shape as to surround regions forming the photodiodes PD in the semiconductor substrate 11 (what is generally called trench isolation). Specifically, for example, the pixel separation portion 20 may be formed by FDTI (Front Deep Trench Isolation), FFTI (Front Full Trench Isolation), RDTI (Reversed Deep Trench Isolation), or RFTI (Reversed Full Trench Isolation).

The terms “front” and “reversed” indicate whether cutting (engraving) for forming the vertical groove is achieved from the front surface Ss side or from the back surface Sb side of the semiconductor substrate 11. Moreover, the terms “deep” and “full” each indicate a trench depth (vertical groove depth). The term “full” refers to formation of a trench penetrating the semiconductor substrate 11, while the term “deep” refers to formation of a trench to a depth not penetrating the semiconductor substrate 11.

FIG. 3 depicts an example of a structure corresponding to RDTI or RETI forming a trench from the back surface Sb side.

In the case of the vertical groove formed in the semiconductor substrate 11 herein, a width of the vertical groove tends to gradually decrease in a direction of progress in cutting. Accordingly, in a case where the trench is formed from the front surface Ss side, such as the cases of FDTI and FFTI, the pixel separation portion 20 is characterized such that the width on the back surface Sb side is smaller than the width on the front surface Ss side. On the contrary, in a case where the trench is formed from the back surface Sb side, such as the cases of RDTI and RFTI, the pixel separation portion 20 is characterized such that the width on the front surface Ss side is smaller than the width on the back surface Sb side.

In the present description, a region separator produced by forming a vertical groove in a semiconductor substrate where a plurality of photoelectric conversion elements is arranged for each pixel will be referred to as a “trench.” This trench may be a groove itself, or may have a form including a necessary film formed in a groove.

A trench constituting the pixel separation portion 20 will hereinafter be referred to as a “trench 20a.”

The fixed charge film 13 is formed on a side wall surface and a bottom surface of the vertical groove described above and on the entire back surface Sb of the semiconductor substrate 11 during a step of forming the pixel separation portion 20. It is preferable that, as the fixed charge film 13, a material capable of generating fixed charge and increasing pinning when deposited on a substrate including silicon or the like be used. As the material of the fixed charge film 13, a high refractive index material film having negative charge or a high dielectric film can be used. Specific examples of the material adoptable as the fixed charge film 13 include an oxide or a nitride containing at least any element of hafnium (Hf), aluminum (Al), zirconium (Zr), tantalum (Ta), and titanium (Ti). Examples of a film forming method include CVD (Chemical Vapor Deposition), sputtering, ALD (Atomic Layer Deposition), and the like. Note that an SiO₂ (silicon oxide) film having a film thickness of approximately 1 nm and reducing an interface level can be simultaneously formed during film formation with use of ALD.

Note that silicon or nitrogen (N) may be added to the film of the material of the fixed charge film 13 in a range not deteriorating insulation properties. A concentration of the added silicon or nitrogen is appropriately determined in a range not deteriorating insulation properties of the film. In such a manner, heat resistance of the film and ion implantation prevention capability during the process can be raised by adding silicon or nitrogen (N).

According to the present embodiment, the fixed charge film 13 having negative charge is formed inside the pixel separation portion 20 and on the back surface Sb of the semiconductor substrate 11. Accordingly, an inversion layer is formed on a surface that is in contact with the fixed charge film 13. In this case, a silicon interface is pinned by the inversion layer. Accordingly, generation of dark current is reduced. Moreover, in the case where a vertical groove for forming the pixel separation portion 20 is formed in the semiconductor substrate 11, physical damage is caused to a side wall and a bottom surface of the vertical groove. In this case, pinning separation may be caused in a peripheral portion of the vertical groove. For overcoming this problem, the fixed charge film 13 having a large quantity of fixed charge is formed on the side wall surface and the bottom surface of the vertical groove to prevent pinning separation in the present embodiment.

The insulation film 14 is embedded in the vertical groove where the fixed charge film 13 is formed, and also provided on the entire back surface Sb of the semiconductor substrate 11. It is preferable that, as the material of the insulation film 14, a material having a refractive index different from a refractive index of the fixed charge film 13 be used, and silicon oxide, silicon nitride, silicon oxynitride, and resin, for example, can be used as the material of the insulation film 14. Moreover, the insulation film 14 can include a material characterized by having no positive fixed charge or having a small quantity of positive fixed charge.

According to the present embodiment, the insulation film 14 is embedded inside the pixel separation portion 20. This configuration separates the photodiodes PD of the respective pixels 2 from each other via the insulation film 14. In this case, leakage of signal charge does not easily occur between the adjoining pixels. Accordingly, in a case where signal charge exceeding a saturation charge quantity (Qs) is generated, leakage of overflowing signal charge into the adjoining photodiode PD can be reduced.

Further, according to the present embodiment, the double structure constituted by the fixed charge film 13 and the insulation film 14 and formed on the back surface Sb side corresponding to the light entrance surface side of the semiconductor substrate 11 also achieves a function as an anti-reflection film by utilizing a difference in refractive index between the fixed charge film 13 and the insulation film 14.

The pixel light shielding portion 21 formed on the insulation film 14 provided on the back surface Sb side of the semiconductor substrate 11 has a grid shape having openings above the photodiodes PD of the respective pixels 2. Specifically, the pixel light shielding portion 21 is formed at a position corresponding to the pixel separation portion 20 as depicted in the plan diagram of FIG. 4 by way of example.

The material that constitutes the pixel light shielding portion 21 is only required to be a material capable of shielding light, and tungsten (W), aluminum (Al), and copper (Cu) can be used as the material that constitutes the pixel light shielding portion 21.

The pixel light shielding portion 21 prevents leakage of light between the adjoining pixels 2, i.e., light leaking into the one pixel 2 instead of entering the other pixel 2 which is only the pixel 2 expected to receive this light.

The flattening film 15 is formed on the pixel light shielding portion 21 and on an area which is included in the insulation film 14 but in which the pixel light shielding portion 21 is not formed, to flatten the back surface Sb side surface of the semiconductor substrate 11. For example, as the material of the flattening film 15, an organic material such as resin can be used.

The filter layer 16 is formed on the flattening film 15, and includes a wavelength filter which transmits light in a predetermined wavelength band for each of the pixels 2. For example, the wavelength filter herein can be a wavelength filter which transmits R (red) light, G (green) light, or B (blue) light, or a wavelength filter which transmits infrared light.

The micro-lens 17 is provided on the filter layer 16 for each of the pixels 2. The micro-lens 17 collects incident light, and the collected light efficiently enters the photodiode PD via the wavelength filter of the filter layer 16.

The wiring layer 12 is formed on the front surface Ss side of the semiconductor substrate 11, and includes a plurality of layers of wires 12a laminated via an interlayer dielectric 12b. The pixel transistors are driven via the wires 12a formed in the wiring layer 12.

According to the sensor device 1 including the pixel array unit 3 described above, light is applied from the back surface Sb side of the semiconductor substrate 11, and the light transmitted through the micro-lenses 17 and the filter layer 16 are photoelectrically converted by the photodiodes PD to generate signal charge. Thereafter, pixel signals corresponding to the signal charge obtained by photoelectric conversion pass through the pixel transistors provided on the front surface Ss side of the semiconductor substrate 11, and are output via the vertical signal lines 9 formed as the predetermined wires 12a of the wiring layer 12.

### (1-4. Structure of Pixel Array Unit of First Embodiment)

In a case where the trench 20a requiring formation of a vertical groove is provided as the pixel separation portion 20 herein, heat treatment such as annealing is performed during a manufacturing process of the sensor device 1. In this case, a crack may be generated in the semiconductor substrate 11 along the trench 20a.

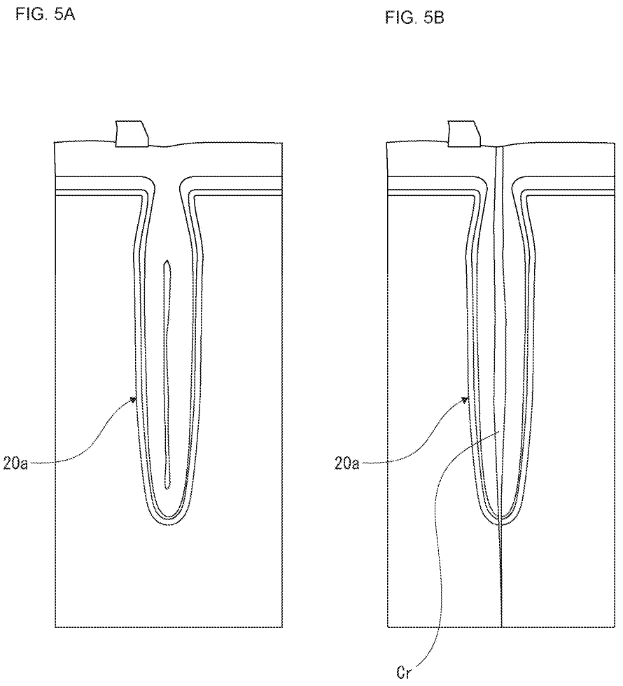

FIG. 5 is an explanatory diagram of a crack, and depicts enlarged images of a cross section of the trench 20a in the semiconductor substrate 11 and an area near the trench 20a. FIG. 5A depicts a state where no crack is generated, while FIG. 5B depicts a state where a crack (expressed as “Cr” in the figure) is generated.

The first embodiment adopts such a method which forms the pixel separation portion 20 in directions different from cleavage directions of crystals of the semiconductor substrate 11 to prevent such crack generation.

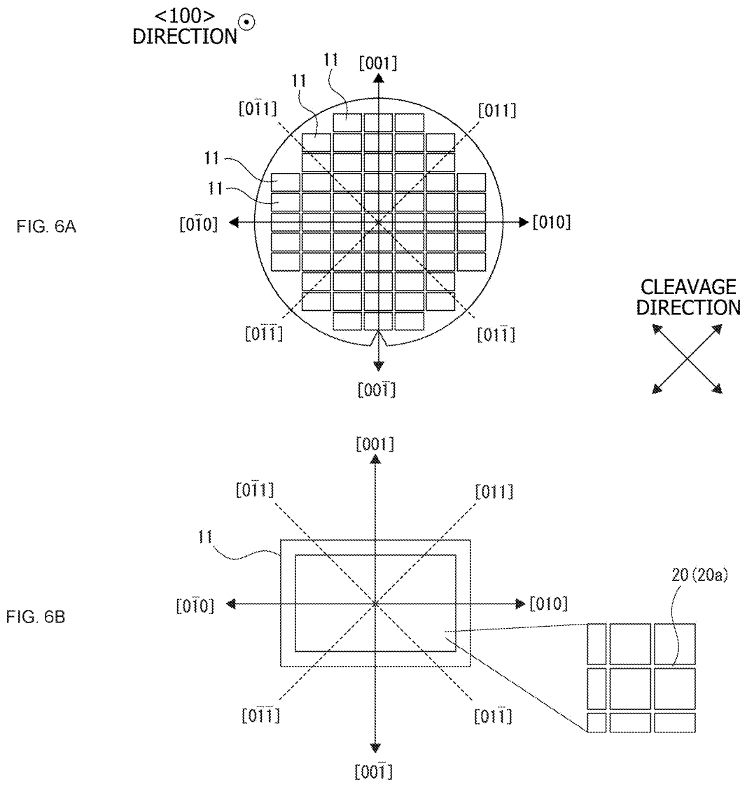

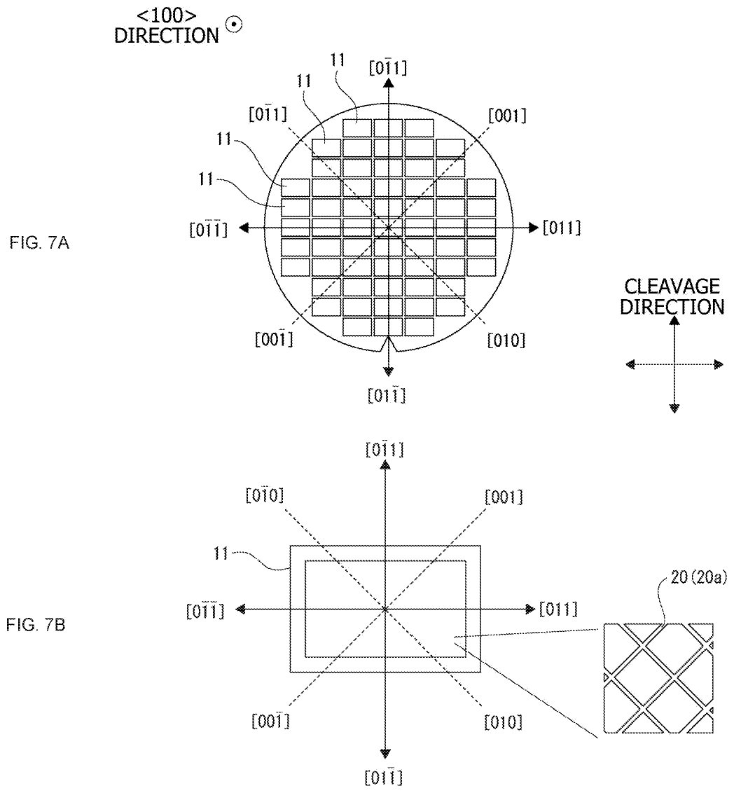

An example of forming directions of the pixel separation portion 20 will be described with reference to FIG. 6 and FIG. 7.

In these FIG. 6 and FIG. 7, FIG. 6A and FIG. 7B each depicts an example of an arrangement mode of the semiconductor substrates 11 on a semiconductor wafer used in the manufacturing process of the sensor device 1, and an example of crystal directions and cleavage directions of the semiconductor wafer.

FIG. 6B and FIG. 7B depict examples of relations between crystal directions of the semiconductor substrate 11 corresponding to the arrangement modes of the semiconductor substrate 11 depicted in FIG. 6A and FIG. 7A by way of example, respectively, and forming directions of the pixel separation portion 20 (trench 20a).

As depicted in FIG. 6 and FIG. 7 referred to above, the semiconductor substrate 11 has a rectangular shape (an oblong shape in the present example) in a plan view.

Meanings of symbols “< >” and “[ ]” included in the figures will be briefly explained herein. These symbols are generally used in crystallography, and the symbol “< >” expresses an equivalent orientation group. Specifically, there exist symmetrical directions in view of an arrangement state of surrounding atoms along a crystal direction [uvw] of a vector OP. These directions are equivalent in view of crystallography, and are collectively expressed as <uvw>. Each of the symbols “[ ]” indicates a direction of a vector from any grid point in a crystal to any different grid point P. Specifically, it is assumed that any grid point in a crystal is designated as an origin O and that crystal axes (directions) are defined as x, y, and z (side lengths of a unit grid are a, b, and c). In this case, the vector OP which extends from the origin O to any different grid point P is expressed as “ua+vb+wc.” This [uvw] is called a crystal direction.

A symbol “( )” is called a Miller index, and expresses a crystal surface containing different three grid points in a crystal. Further, there also exist crystal surfaces equivalent to this crystal surface in view of crystallography as in the case of directions described above.

In FIG. 6 and FIG. 7, a thickness direction of the semiconductor wafer (and the semiconductor substrate 11) is aligned with <100> direction.

While a symbol given a bar (“-”) at an upper part of a numerical value “1” (hereinafter expressed as “1-bar”) is used for the crystal direction of “[ ]” in the figures herein, the “1-bar” will be expressed as “1⁻” for convenience of characteristic expressions in the present description.

In FIG. 6 and FIG. 7, a wafer having directions of [001], [011], [010], [011⁻], [001⁻], [01⁻1⁻], [01⁻0], and [01⁻1] parallel to a surface direction (a direction perpendicular to a thickness direction) is used as the semiconductor wafer. In a case where the semiconductor substrate 11 is a silicon substrate as in the present example, the directions [011], [01⁻1⁻], [01⁻1], and [011⁻] of these crystal directions correspond to cleavage directions.

According to the example in FIG. 6, the semiconductor substrates 11 are arranged such that a longitudinal direction is parallel to the directions of and [01⁻0] and a lateral direction is parallel to the directions of and [001⁻] in the semiconductor wafer as depicted in FIG. 6A.

In addition, as depicted in FIG. 6B, the trench 20a for pixel separation in each of the semiconductor substrates 11 in this case extends in the directions of [001], [001⁻], [010], and [01⁻0].

Accordingly, the pixel separation portion 20 in this case is formed in directions different from the cleavage directions of crystals of the semiconductor substrates 11.

As a result, prevention of crack generation in each of the semiconductor substrates 11 is achievable.

Meanwhile, according to the example in FIG. 7, the semiconductor substrates 11 are arranged such that a longitudinal direction is parallel to the directions of and [01⁻1⁻] and a lateral direction is parallel to the directions of [01⁻1] and [011⁻] in the semiconductor wafer as depicted in FIG. 7A.

In addition, as depicted in FIG. 7B, the trench 20a in each of the semiconductor substrates 11 in this case extends in the directions of [001], [001⁻], [01⁻0], and [010].

In the example depicted in FIG. 7, the pixel separation portion 20 is similarly formed in directions different from the cleavage directions of the crystals of the semiconductor substrates 11, and therefore, prevention of crack generation in each of the semiconductor substrates 11 is achievable.

The forming directions of the pixel separation portion 20 in FIG. 6 and FIG. 7 are presented only by way of example.

In a case where a silicon substrate is used as the semiconductor substrate 11, cleavage directions are [01⁻1], [011⁻], [011], [01⁻1⁻], [1⁻01], [101⁻], [101], [1⁻01⁻], [1⁻10], [11⁻0], [110], and [1⁻1⁻0]. Accordingly, in a case where a silicon substrate is used as the semiconductor substrate 11 as in the present example, prevention of crack generation is achievable by forming the pixel separation portion 20 in directions different from these directions.

Moreover, as depicted in FIG. 6 and FIG. 7, the pixel separation portion 20 is formed in directions [001], [001⁻], [01⁻0], and different from the cleavage directions.

In this case, the trench 20a of the pixel separation portion 20 is formed in directions shifted from the cleavage directions by 45 degrees.

Accordingly, an effect of crack generation prevention can be maximized from a viewpoint of a relation between the forming directions of the trench 20a and the cleavage directions.

The trench 20a herein is basically formed only on boundaries between the pixels as the pixel separation portion 20. In other words, assuming that a region where a plurality of pixels 2 is two-dimensionally arranged in the semiconductor substrate 11 is a pixel arrangement region Ap, the trench 20a is not basically formed in an outermost peripheral portion of the pixel arrangement region Ap.

However, in a case where the trench 20a is formed only in boundary portions between the pixels 2, this configuration may generate a crack from the outermost peripheral portion of the pixel arrangement region Ap.

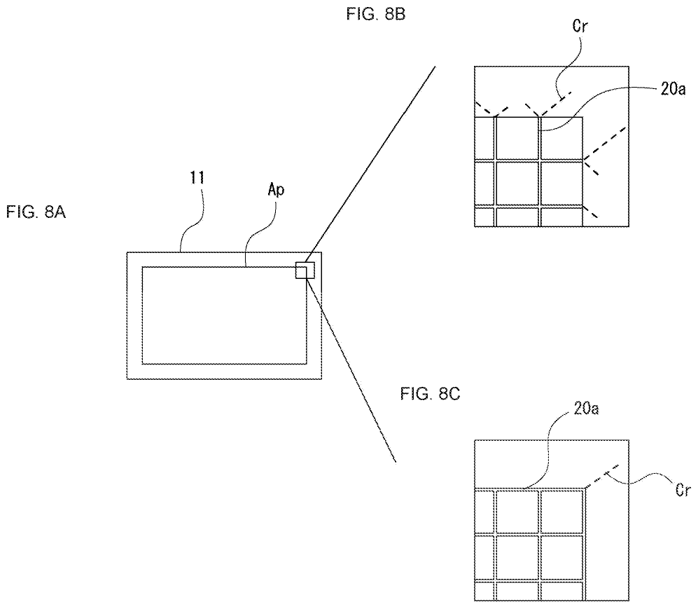

FIG. 8 is an explanatory diagram depicting this point. FIG. 8A is an explanatory diagram of the pixel arrangement region Ap in the semiconductor substrate 11, while FIG. 8B is an enlarged diagram of a partial region near the outermost periphery of the pixel arrangement region Ap.

In a case where the trench 20a is formed only in the boundary portions between the pixels 2, the trench 20a is discontinued at positions of outermost peripheral sides of the pixel arrangement region Ap. Accordingly, a crack is easily generated from these discontinued portions (see “Cr” indicated by dotted lines in FIG. 8B).

Accordingly, for solving this problem, a configuration which has the trench 20a along the outermost peripheral sides of the pixel arrangement region Ap in the semiconductor substrate 11 can be adopted.

This configuration prevents the foregoing discontinued portions of the trench 20a from being produced in the outermost peripheral portion of the pixel arrangement region Ap, and thus prevents crack generation from these discontinued portions.

However, in a case where the trench 20a is formed around an entire outer edge of the pixel arrangement region Ap which is a rectangular region, each bending angle of the trench 20 has a right angle at four corners of the pixel arrangement region Ap. A crack is more easily generated from the four corners of the pixel arrangement region Ap as the bending angles of the four corners approaches 90 degrees for the trench 20a formed on the outermost peripheral sides of the pixel arrangement region Ap.

FIG. 8C depicts an image of a crack generated from one of the four corners (see “Cr” indicated by a dotted line in the figure). As depicted in the figure, the crack in this case is generated in an oblique direction of the semiconductor substrate 11 in the plan view.

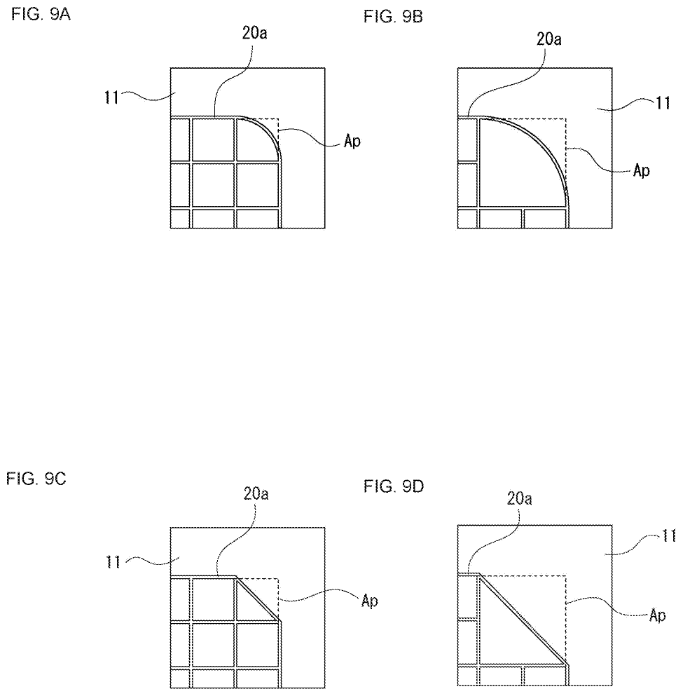

Accordingly, the trench 20a formed on the outermost peripheral sides of the pixel arrangement region Ap may have a chamfered shape at each of portions corresponding to the four corners of the pixel arrangement region Ap as depicted in FIG. 9 by way of example.

The chamfered shape herein refers to a shape having a reduced bending angle or a rounded corner with respect to a corner that has a bending angle of 90 degrees and that is formed by simply connecting two sides crossing at right angles.

FIG. 9A and FIG. 9B each depict an example of a shape having a rounded corner as an example of a chamfered shape. FIG. 9A is an example where a one-pixel region is chamfered, while FIG. 9B is an example where a two-by-two pixel region, i.e., a four-pixel region, is chamfered.

FIG. 9C and FIG. 9D each depict a shape having a bending angle of 45 degrees as an example of a chamfered shape. FIG. 9C is an example where a one-pixel region is chamfered, while FIG. 9D is an example where a two-by-two pixel region, i.e., a four-pixel region, is chamfered.

The configuration in which the trench 20a formed in the outermost peripheral portion of the pixel arrangement region Ap as described above has a chamfered shape for each of the portions of the four corners can reduce crack generation from these portions of the four corners.

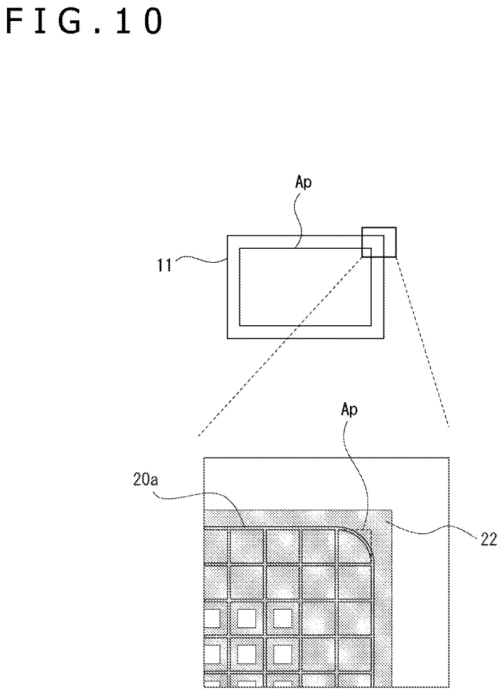

For reducing crack generation from the outermost peripheral portion of the pixel arrangement region Ap, it is effective to form a metal film 22 covering an upper part of the trench 20a formed at least along the outermost peripheral sides of the pixel arrangement region Ap as depicted in FIG. 10 by way of example.

In this case, the metal film 22 is provided in such a manner as to cover the upper part of the trench 20a formed along the outermost peripheral sides of the pixel arrangement region Ap and cover the entire trench 20a as the pixel separation portion 20 in the pixel arrangement region Ap. In this case, the metal film 22 is formed in such a manner as to have an opening through which light enters and reaches the photodiode PD, for each of the pixels 2 at least in the effective pixel region in the pixel arrangement region Ap.

Note that it can be considered to adopt an Al film as the metal film 22, for example. Moreover, the metal film 22 can also function as a light shielding film for reducing flares.

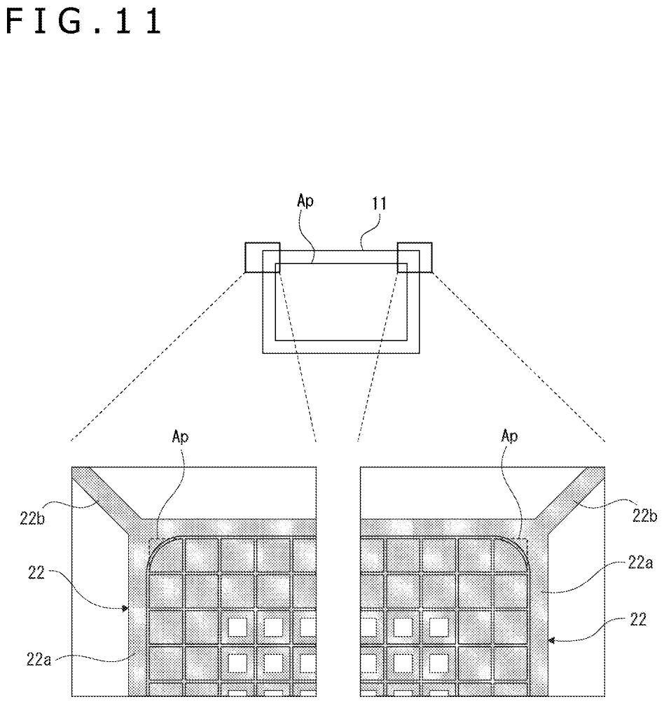

FIG. 11 is an explanatory diagram of a modification of the metal film 22.

As depicted in the figure, the metal film 22 in this case has a portion 22a covering at least the trench 20a formed along the outermost peripheral sides of the pixel arrangement region Ap (in the depicted example, each of the four corners has a chamfered shape) and portions 22b extending in oblique directions from the four corners of the portion 22a.

The oblique directions herein refer to directions corresponding to crystal directions of [01⁻1], [011⁻], [011], [01⁻1⁻], [1⁻01], [101⁻], [101], [1⁻01⁻], [1⁻10], [11⁻0], [110], and [1⁻1⁻0]. In other words, the portions 22b can be considered as portions formed in the cleavage directions of the semiconductor substrate 11.

This configuration prevents crack generation in oblique directions from the four corners of the trench 20a formed around the outermost periphery of the pixel arrangement region Ap.

### 2. Second Embodiment

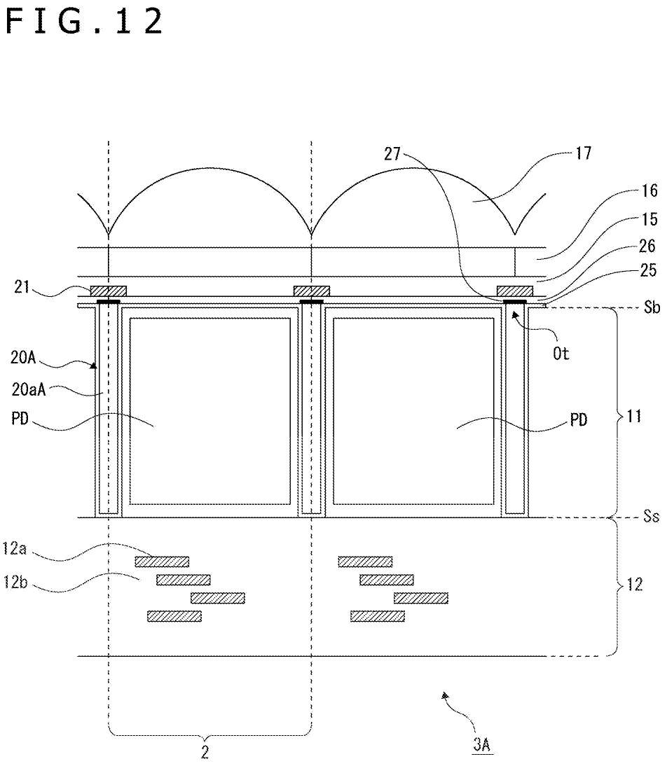

A second embodiment will be subsequently described with reference to FIG. 12 to FIG. 19.

The second embodiment prevents crack generation in the semiconductor substrate 11 caused by contact between portions of an insulation film in a vertical groove Vt during manufacture of the sensor device 1 in a case where the insulation film is formed on a side wall portion of the vertical groove Vt for pixel separation (i.e., in a case where an insulation film is formed in an outermost peripheral portion of the trench).

Note that parts which are presented in the following description and are similar to the corresponding parts already explained will be given identical reference signs and will not be repeatedly explained.

FIG. 12 is a cross-sectional diagram for explaining a schematic structure of a pixel array unit 3A according to the second embodiment.

The pixel array unit 3A is different from the pixel array unit 3 in the first embodiment in a point that a pixel separation portion 20A is formed in place of the pixel separation portion 20. In other words, the difference is a point that a trench 20aA is formed in place of the trench 20a.

The trench 20aA has a first insulation film 25 in an outermost peripheral portion. As depicted in the figure, the first insulation film 25 is continuously formed from the outermost peripheral portion of the trench 20aA to an upper part of the back surface Sb of the semiconductor substrate 11.

Similarly to the trench 20A, the trench 20aA is formed by engraving the back surface Sb of the semiconductor substrate 11. In this case, the back surface Sb of the semiconductor substrate 11 is considered as a surface which is one of two surfaces crossing the thickness direction of the semiconductor substrate 11 at right angles and which is defined as a surface on the side where the trench is engraved, and corresponds to a “first surface” in the claims.

The trench 20aA has a cavity inside the first insulation film 25. A back surface Sb side end of the trench 20aA is not closed by the first insulation film 25. A portion of the cavity located at the back surface Sb side end of the trench 20aA and not closed by the first insulation film 25 as described above will be referred to as an “opening Ot.”

The pixel array unit 3A has a second insulation film 26 formed on the first insulation film 25. As depicted in the figure, the second insulation film 26 is formed across an upper part of the opening Ot of the trench 20aA.

According to the present example, the upper part of the opening Ot of the trench 20aA is covered by a resin film 27 patterned in such a manner as to trace an upper part of the trench 20a in the plan view. The second insulation film 26 formed on the resin film 27 is provided in such a manner as to extend across the upper part of the opening Ot.

Each of the first insulation film 25 and the second insulation film 26 herein may be an oxide film including silicon oxide or the like.

Note that each of a structure in an upper layer portion with respect to the second insulation film 26 and a structure in a lower layer portion with respect to the semiconductor substrate 11 is similar to the corresponding structure in the pixel array unit 3, and therefore is not repeatedly explained.

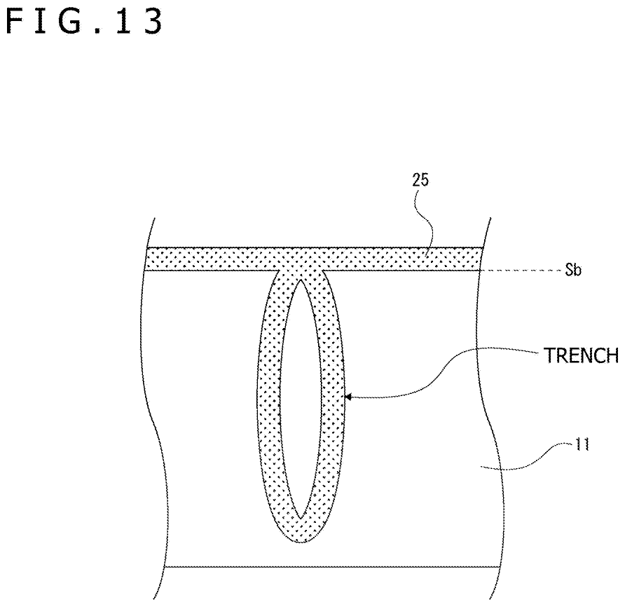

For producing the trench provided for pixel separation and structured to have the insulation film on the outermost peripheral portion, it can be considered herein to form the insulation film (indicated as the first insulation film 25 in the figure) which closes the back surface Sb side of the trench as depicted in FIG. 13 by way of example.

However, in the case where the insulation film is formed in such a manner as to close the back surface Sb side of the trench, a crack is easily generated for the following reason.

First, even if the insulation film is formed in such a manner as to close the back surface Sb side of the trench, a slight clearance is produced without complete contact between portions of the insulation film in an actual situation. This clearance portion adheres and shrinks according to heat treatment during the manufacturing process of the sensor device 1, and produces stress. As a result, a crack is easily generated in response to this stress.

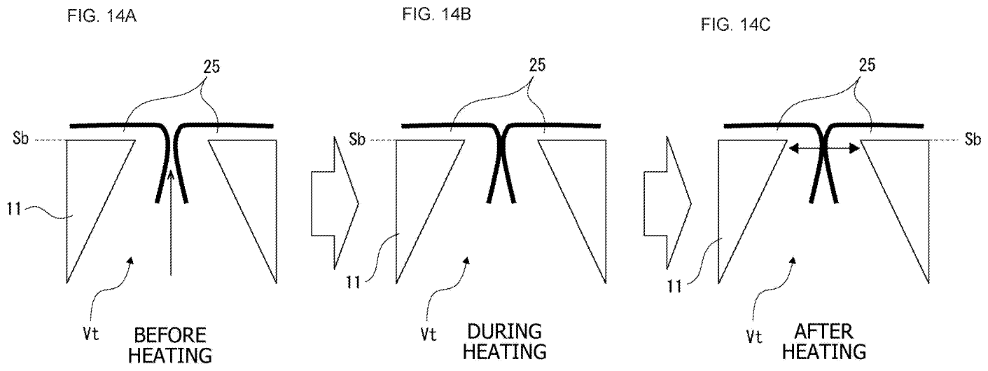

FIG. 14 is an explanatory diagram depicting this point.

FIG. 14A schematically depicts a state of a portion near the vertical groove Vt in the semiconductor substrate 11 during formation of the first insulation film 25. Heat treatment for annealing is performed after formation of the first insulation film 25. Accordingly, the state in FIG. 14A can be considered as a state before heating.

Even if the first insulation film 25 is formed in such a manner as to close the back surface Sb side opening of the vertical groove Vt, complete contact between portions of the first insulation film 25 is not achieved in an actual situation. In this case, a small clearance is produced as indicated by a vertical arrow in the figure.

If the heat treatment for annealing is performed in this state, the portions of the first insulation film 25 adhere to each other by heat expansion as depicted in FIG. 14B by way of example. Thereafter, the first insulation film 25 shrinks according to a temperature drop after the heat treatment. In this case, stress indicated by lateral arrows in FIG. 14C between the adhering portions of the first insulation film 25, i.e., stress acting in a such a direction as to separate the adhering portions of the first insulation film 25 from each other, is produced according to the heat shrink after the heat treatment.

Such stress causes crack generation.

Moreover, a width of the trench at a cross portion (a portion where portions of the trench cross each other) is different from a width of the trench at the other portion (hereinafter referred to as a “non-cross portion”). In this case, even if the first insulation film 25 is formed in such a manner as to close the back surface Sb side of the trench, the closure of the trench by the first insulation film 25 starts from the non-cross portion, and then reaches the cross portion. Accordingly, during the process for forming the first insulation film 25, a state where the entire vertical groove Vt is opened and a state where the non-cross portion of the vertical groove Vt is closed and the cross portion is not closed are present.

As described above, closure of the cross portion is achieved with delay from closure of the non-cross portion. Accordingly, a film quality deteriorated portion of the first insulation film 25 is produced in the trench, and a crack is also easily generated by this film quality deteriorated portion.

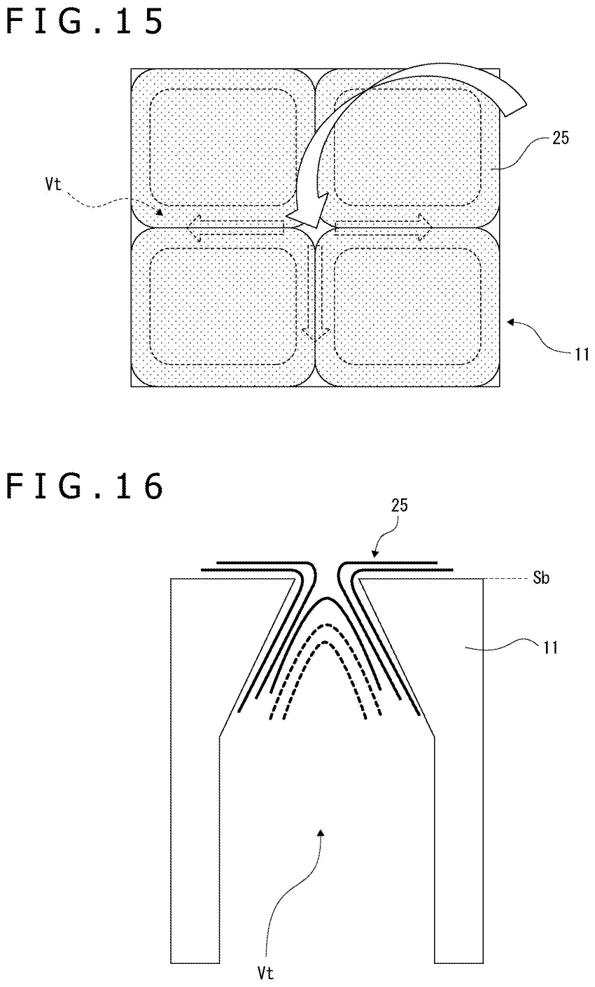

This point will be more detailed with reference to FIG. 15 and FIG. 16.

FIG. 15 schematically depicts a state of the non-cross portion closed by the first insulation film 25 and the cross portion not closed in a film forming step of the first insulation film 25 in the plan view.

In this state, film forming gas does not directly enter the vertical groove Vt in the non-cross portion but enters the inside of the vertical groove Vt in the non-cross portion via a not-closed part of the cross portion.

As described above, the film forming gas enters with delay from the not-closed part of the cross portion into the vertical groove Vt of the non-cross portion. Accordingly, as depicted in a cross-sectional view of FIG. 16, the first insulation film 25 (indicated by thick broken lines in the figure) is additionally formed by the film forming gas entering with delay in the vertical groove Vt of the non-cross portion below the first insulation film 25 (indicated by thick solid lines in the figure) already closing the opening of the vertical groove Vt.

In such a manner, the portion of the first insulation film 25 formed by the film forming gas having entered from the cross portion into the non-cross portion is produced in an O₂ plasma insufficient state. Accordingly, uncomplete reaction is caused, and the film quality is deteriorated. A crack is easily generated at such a film quality deteriorated portion.

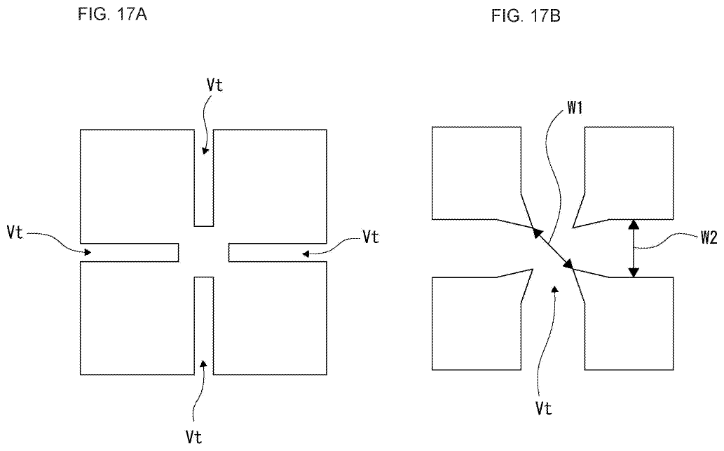

Accordingly, for preventing the film quality deteriorated portion described above from being generated, it can be considered herein to adopt a method which does not form the vertical groove Vt at the cross portion as depicted in FIG. 17A or a method which equalizes a width W1 of the vertical groove Vt at the cross portion with a width W2 of the vertical groove Vt at the non-cross portion as depicted in FIG. 17B, for example.

However, in a case where the method depicted in FIG. 17A is adopted, elimination of the trench at the cross portion may lower shielding performance between the pixels. In addition, according to the method which equalizes the widths W1 and W2 as depicted in FIG. 17B, formation of the vertical groove Vt becomes more difficult. In this case, costs may be raised, or in-plane variations may be increased due to difficulty in equalization of the trench shape between the pixels.

According to the second embodiment, therefore, the first insulation film 25 is formed in such a manner as not to close the back surface Sb side portion of the vertical groove Vt. In this case, the trench 20aA has a structure including the opening Ot on the back surface Sb side as described above with reference to FIG. 12.

This configuration can prevent crack generation caused by stress produced according to the heat shrink of the first insulation film 25 and the film quality deteriorated portion described above, while avoiding lowering of shielding performance between the pixels, a rise of costs caused by a processing difficulty, and in-plane variations.

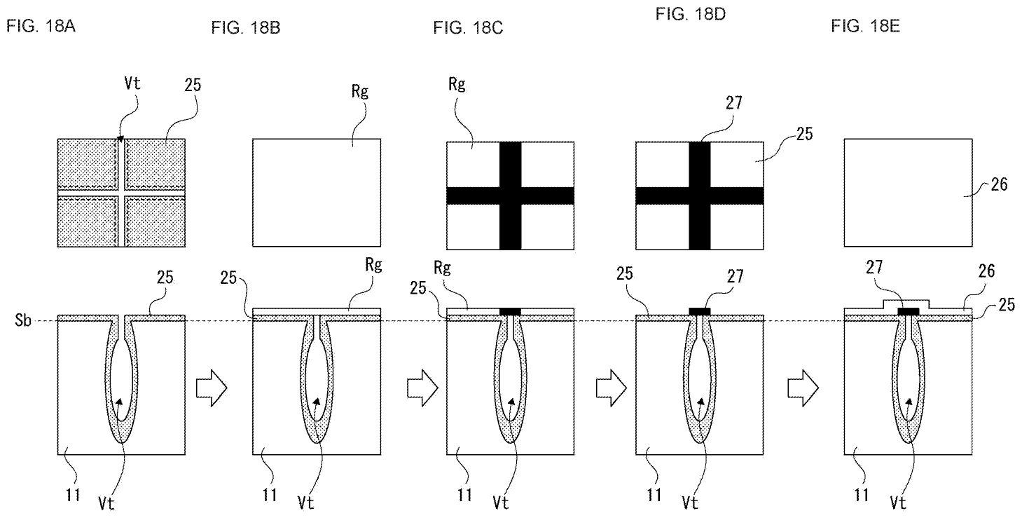

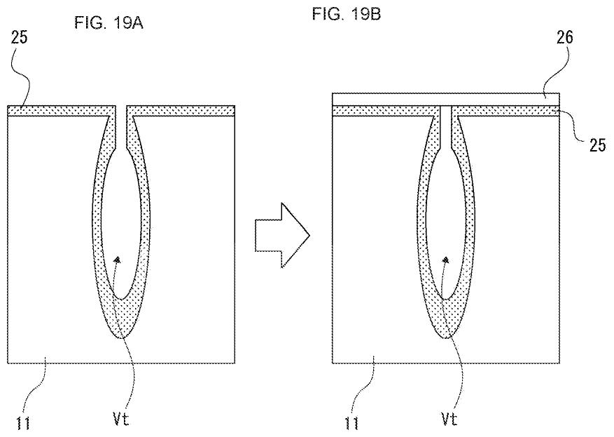

FIG. 18 is an explanatory diagram depicting a manufacturing method of the sensor device 1 according to the second embodiment.

The description particularly focuses on steps associated with formation of the first insulation film 25, the second insulation film 26, and the resin film 27 herein. In FIG. 18, FIG. 18A to FIG. 18D each depict a state in a cross-sectional view in a lower part and a state in a plan view (a plan view on the back surface Sb side) in an upper part.

First, the first insulation film 25 is formed on a target which is the back surface Sb side of the semiconductor substrate 11 having the vertical groove Vt engraved from the back surface Sb side, such that the back surface Sb side opening of the vertical groove Vt is not closed (FIG. 18A). For example, this forming step of the first insulation film 25 is achievable by a film forming process such as ALD (atomic layer deposition).

Subsequently, a resist Rg is applied to an upper part of the formed first insulation film 25 by spin-coating or the like, for example (FIG. 18B), and the applied resist Rg is exposed with use of a pattern which traces the upper part of the vertical groove Vt, to achieve a hardening process for the resist Rg (FIG. 18C). Thereafter, a not-hardened portion of the resist Rg is removed (FIG. 18D). As a result, the resin film 27 is formed in such a manner as to cover the upper part of the opening which is a portion where the first insulation film 25 is not formed on the back surface Sb side of the vertical groove Vt.

Moreover, the second insulation film 26 is formed on the first insulation film 25 and on the resin film 27 by a film forming process such as CVD (chemical vapor deposition) and sputtering (FIG. 18E).

In this manner, the structure of the pixel array unit 3A depicted in FIG. 12 can be produced.

FIG. 19 is a diagram for explaining another example of the insulation film forming method according to the second embodiment.

This different example is similar to the case depicted in FIG. 18 in a point that the first insulation film 25 is formed on a target which is the back surface Sb side of the semiconductor substrate 11 having the vertical groove Vt engraved from the back surface Sb side, such that the back surface Sb side opening of the vertical groove Vt is not closed (FIG. 19A).

According to this different example, the second insulation film 26 is formed by CVD on the first insulation film 25 formed in such a manner as not to close the back surface Sb side opening of the vertical groove Vt.

The second insulation film 26 can be formed in such a manner as not to close the back surface Sb side opening of the vertical groove Vt, by applying CVD to film formation of the second insulation film 26. In other words, the second insulation film 26 extending across an upper part of the opening Ot of the trench 20aA can be formed.

Further, as still another example, in a case where ALD is used for forming the first insulation film 25, the second insulation film 26 can be formed on the first insulation film 25 by ALD having a film forming temperature higher than a film forming temperature of the first insulation film 25.

In this case, for example, the film forming temperature of the first insulation film 25 may be approximately 300 degrees, while the film forming temperature of the second insulation film 26 may be approximately 400 degrees.

When the second insulation film 26 is formed by ALD having the higher film forming temperature than the film forming temperature of the first insulation film 25, a material of the second insulation film 26 does not easily enter the opening formed on the back surface Sb side of the vertical groove Vt, during formation of the second insulation film 26. Accordingly, as in the case of B in FIG. 19, the second insulation film 26 extending across the upper part of the opening Ot of the trench 20aA can be formed.

### 3. Third Embodiment

A third embodiment prevents crack generation caused by stress produced in a metal film according to heat treatment during the manufacturing process in a case where the metal film is formed in the trench.

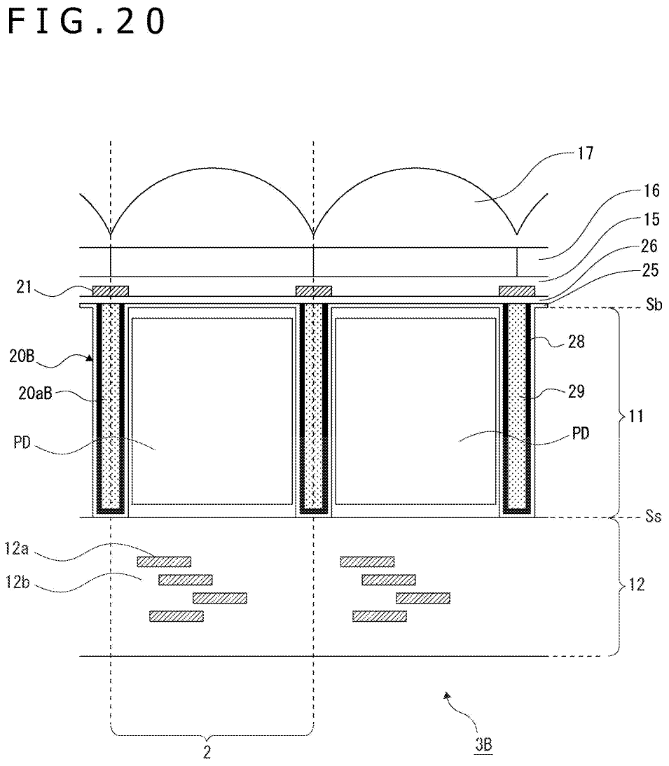

FIG. 20 is a cross-sectional diagram for explaining a schematic structure of a pixel array unit 3B according to the third embodiment.

The pixel array unit 3B is different from the pixel array unit 3 of the first embodiment in a point that a pixel separation portion 20B is formed in place of the pixel separation portion 20. In other words, the difference is a point that a trench 20aB is formed in place of the trench 20a.

The trench 20aB has the first insulation film 25 in an outermost peripheral portion. As depicted in the figure, the first insulation film 25 is continuously formed from the outermost peripheral portion of the trench 20aB to an upper part of the back surface Sb of the semiconductor substrate 11.

Moreover, the trench 20aB has a metal film 28 inside the first insulation film 25. The metal film 28 functions as a light shielding film between the pixels 2, and also functions as a reflection film. This function as a reflection film improves light collection performance of the photodiode PD.

Further, a similar heat expansion material 29 is embedded inside the metal film 28 in the trench 20aB. Note that the similar heat expansion material 29 will be described below.

The pixel array unit 3B has the second insulation film 26 provided on the trench 20aB and on the first insulation film 25 formed on the back surface Sb of the semiconductor substrate 11.

Note that each of a structure in an upper layer portion with respect to the second insulation film 26 and a structure in a lower layer portion with respect to the semiconductor substrate 11 is similar to the corresponding structure in the case of the pixel array unit 3, and therefore is not repeatedly explained.

In a case where the metal film is provided herein so as to improve light shielding performance or light collection performance in the trench provided for pixel separation, stress corresponding to a heat shrink of the metal film is produced according to heat treatment for annealing or the like during the manufacturing process of the sensor device 1. In this case, a crack may be generated in the semiconductor substrate 11 according to this stress.

According to the present embodiment, therefore, an interior of the metal film 28 formed in the trench 20aB is filled with the similar heat expansion material 29. The similar heat expansion material 29 herein refers to a material having a heat expansion characteristic similar to that of a material constituting the semiconductor substrate 11.

In a case where the semiconductor substrate 11 is a silicon substrate as in the present example, silicon is used as the similar heat expansion material 29. In this case, it can be considered to use, as the similar heat expansion material 29, polysilicon (polycrystalline silicon) or amorphous silicon, for example.

As described above, the similar heat expansion material 29 is embedded inside the metal film in the trench 20aB. Accordingly, even if a heat shrink is caused by heat treatment during manufacture of the sensor device 1, the degrees of the heat shrink outside the trench 20aB and inside the trench 20aB are equalized. This configuration can reduce stress produced at an entrance portion of the trench 20aB (i.e., the back surface Sb side portion in the present example) according to the heat treatment described above.

Accordingly, this configuration achieves prevention of crack generation caused by stress produced at the entrance portion of the trench 20aB according to heat treatment of the manufacturing process of the sensor device 1, while improving the light collection performance for the photoelectric conversion element with use of the metal film 28 formed inside the trench 20aB.

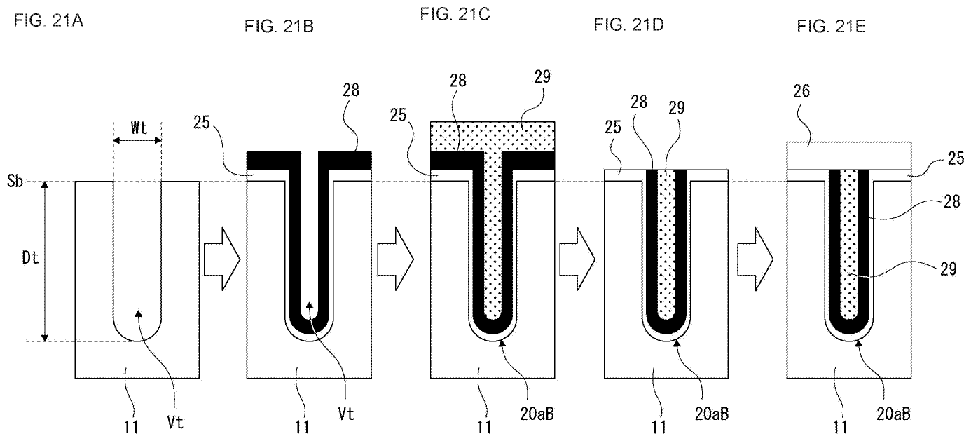

FIG. 21 is an explanatory diagram depicting a manufacturing method of the sensor device 1 according to the third embodiment.

The description herein particularly focuses on steps associated with formation of the trench 20aB and the second insulation film 26.

First, the semiconductor substrate 11 is engraved from the back surface Sb side to form the vertical groove Vt (FIG. 21A). According to the present example, a depth Dt of the vertical groove Vt is approximately 3 μm, for example, while a width Wt of the vertical groove Vt is approximately 200 nm, for example.

Subsequently, the first insulation film 25 and the metal film 28 are formed (FIG. 21B). Specifically, the first insulation film 25 is first formed by a film forming process such as ALD on a target which is the back surface Sb of the semiconductor substrate 11 where the vertical groove Vt is formed. In this manner, the first insulation film 25 is formed on the back surface Sb of the semiconductor substrate 11 and a side wall portion of the vertical groove Vt.

Thereafter, the metal film 28 including Al or the like is formed on the first insulation film 25 thus formed, by a film forming process such as sputtering.

It is preferable that the first insulation film 25 herein have a film thickness of approximately 10 nm, for example, on the side wall portion of the vertical groove Vt. Meanwhile, it is preferable that the metal film 28 have a film thickness of approximately 40 nm, for example, on the side wall portion of the vertical groove Vt.

Moreover, the similar heat expansion material 29 (silicon in the present example) is formed on the metal film 28 by a film forming process such as CVD (FIG. 21C). In this manner, the similar heat expansion material 29 is embedded inside the metal film 28 in the vertical groove Vt to obtain a structure of the trench 20aB.

In addition, at this time, the similar heat expansion material 29 is also formed on the metal film 28 formed on an upper layer of the back surface Sb of the semiconductor substrate 11.

After the similar heat expansion material 29 is formed, the upper part above the first insulation film 25 is removed by a polishing process such as CMP (Chemical Mechanical Polishing) (FIG. 21D). Thereafter, the second insulation film 26 is formed on the trench 20aB and on the first insulation film 25 provided on the back surface Sb, by a film forming process such as ALD (FIG. 21E).

As can be understood from the explanation with reference to FIG. 21, according to the present example, the metal film 28 is first formed, and the similar heat expansion material 29 is embedded inside the metal film 28. Thereafter, the second insulation film 26 (the SiO₂ film in the present example) is formed.

In this manner, stress produced at the entrance portion of the trench 20aB according to annealing of the second insulation film 26 can be reduced. Accordingly, a crack generation prevention effect can be offered also in this point.

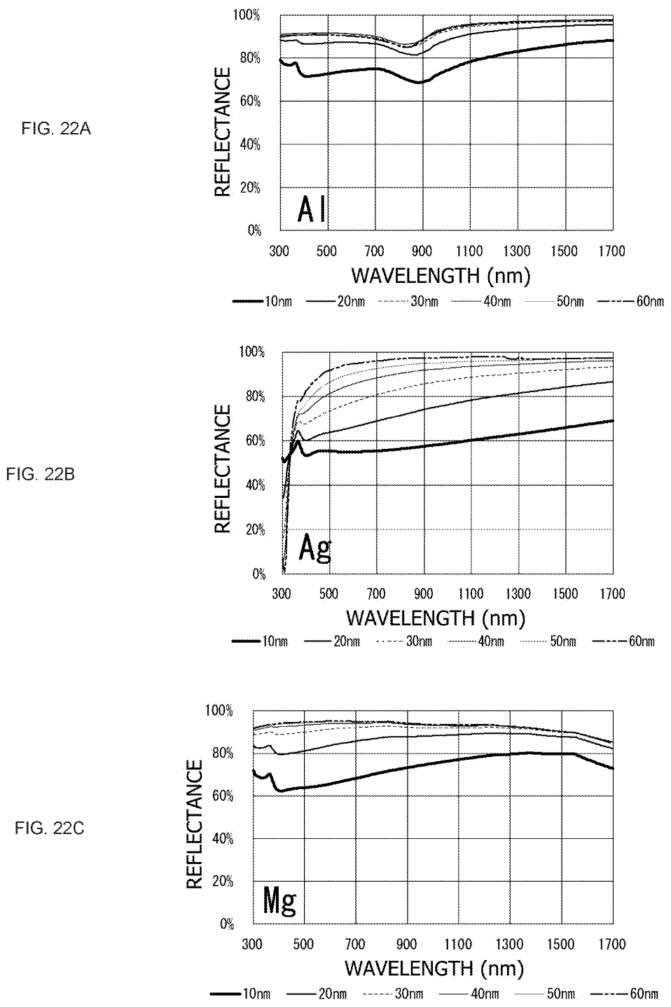

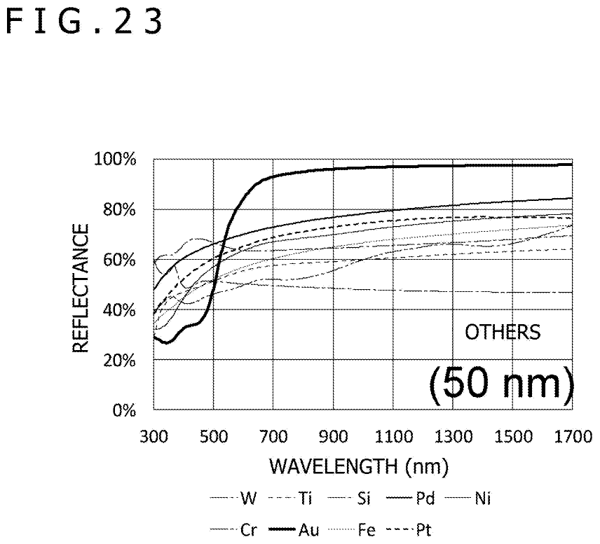

The material and the film thickness of the metal film 28 will be considered herein with reference to FIG. 22 and FIG. 23.

FIG. 22 illustrates reflectance characteristics for wavelengths for each of Al (FIG. 22A), Ag (FIG. 22B), and Mg (FIG. 22C) and for each film thickness. The reflectance in FIG. 22 is a measurement result in a case where a film thickness of the first insulation film 25 and a thickness of the similar heat expansion material 29 are set to 10 nm and 80 nm, respectively, for a layer structure including the first insulation film 25 (SiO₂), the metal film 28, and the similar heat expansion material 29 formed in the trench 20aB.

For example, it can be considered that any one of Al, Ag, Mg described above is adopted as the material of the metal film 28.

In consideration of a wavelength band of visible light (approximately from 400 to 800 nm), the film thickness is preferably 30 nm or larger for Al illustrated in FIG. 22A, so as to obtain reflectance of 80% or higher.

Moreover, the film thicknesses are preferably 50 nm or larger and 30 nm or larger for Ag illustrated in FIG. 22B and Mg illustrated in FIG. 22C, respectively, so as to similarly obtain reflectance of 80% or higher.

FIG. 23 illustrates reflectance characteristics for wavelengths for each of W, Ti, Si, Pd, Ni, Cr, Au, Fe, and Pt as a reference. Note that all the film thicknesses of these materials constituting the metal film 28 are set to 50 nm.

As apparent from FIG. 23, in a case where Si is used in place of the metal film 28, i.e., in a case where the entire interior of the first insulation film 25 is filled with Si, sufficient reflectance cannot be obtained. Moreover, Au has high reflectance on the whole, but the reflectance of Au considerably lowers in the wavelength band of visible light, particularly in a region of 600 nm or lower.

On the basis of these results of FIG. 23, it is obvious that reflectance of 80% or higher is difficult to obtain in the wavelength band of visible light when W, Ti, Si, Pd, Ni, Cr, Au, Fe, and Pt are used.

As the similar heat expansion material 29 herein, liquid silicon can also be used.

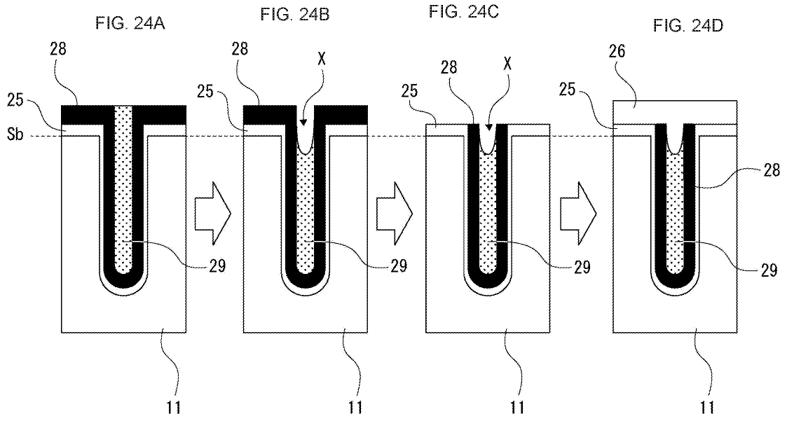

FIG. 24 is an explanatory diagram depicting an effect offered in a case where liquid silicon is used as the similar heat expansion material 29.

In the case where liquid silicon is used as the similar heat expansion material 29, the liquid silicon is applied by spin coating, for example, after the metal film 28 is formed as explained above with reference to FIG. 21B.

FIG. 24A depicts a state where the similar heat expansion material 29 as liquid silicon is embedded inside the metal film 28 by this application.

In the case of use of liquid silicon, annealing is carried out after liquid silicon is applied. The annealing thus carried out produces a recess protruding toward the bottom side of the trench is formed in the portion filled with silicon inside the metal film 28, as indicated by “X” in FIG. 24B (hereinafter referred to as a “recess X”). The recess X is formed by a decrease in a volume of silicon caused by dehydrogenation according to annealing.

After annealing, the part above the first insulation film 25 is removed by a polishing process such as CMP as depicted in FIG. 24C. Thereafter, the second insulation film 26 is formed by a film forming process such as ALD as depicted in FIG. 24D.

At this time, the second insulation film 26 is also formed in the recess X. When the second insulation film 26 is formed in the recess X as described above, the second insulation film 26 (e.g., SiO₂) formed in the recess X is produced not on the side surface but from above at the entrance portion of the trench. Accordingly, stress produced at the entrance portion of the trench according to the heat treatment can be reduced in this point.

Note that the first insulation film 25 may also be constituted by a laminated structure film where an insulation film including SiO₂ or the like is laminated on the fixed charge film 13 described above.

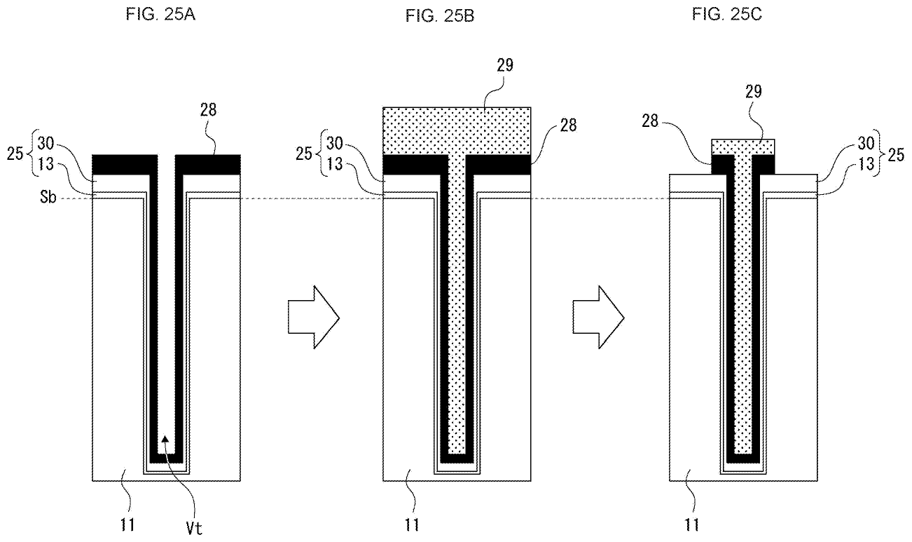

A specific manufacturing method will be described with reference to FIG. 25. Described with reference to FIG. 25 will be an example of a manufacturing method corresponding to a case where the sensor device 1 is a distance measuring sensor handling distance measurement by a ToF (Time of Flight) system such as an indirect ToF system and a direct ToF system.

In this case, for the semiconductor substrate 11 having the vertical groove Vt, the fixed charge film 13 is formed on the side wall portion of the vertical groove Vt and the back surface Sb of the semiconductor substrate 11. An insulation film 30 is then formed on the fixed charge film 13. Thereafter, the metal film 28 is formed on the insulation film 30 (FIG. 25A).

The fixed charge film 13 and the insulation film 30 constitute the first insulation film 25. The metal film 28 is formed on the first insulation film 25.

Subsequently, the similar heat expansion material 29 (silicon in the present example) is formed on the metal film 28 by a film forming process such as CVD, for example (FIG. 25B). In this manner, the similar heat expansion material 29 is embedded inside the metal film 28 in the vertical groove Vt to obtain a structure of the trench 20aB. In addition, at this time, the similar heat expansion material 29 is also formed on the metal film 28 formed on an upper layer of the back surface Sb of the semiconductor substrate 11.

In this case, the part above the first insulation film 25 is removed by etching (FIG. 25C) after the similar heat expansion material 29 is formed. At this time, for removing the metal film 28 and the similar heat expansion material 29, not all the part of the layer above the first insulation film 25 is removed, but a portion along the trench is left as depicted in the figure.

In the case of handling the ToF system herein, the depth Dt of the vertical groove Vt is made larger than approximately 3 μm previously presented by way of example, according to a wavelength of light (e.g., infrared light) corresponding to light to be received. For example, the depth Dt may be set to approximately 7 μm. In this manner, the light collection performance of the metal film 28 can be raised according to the wavelength of light received by the iToF system.

Note that the width Wt of the vertical groove Vt may be set to approximately 700 nm, for example.

In this case, it is further preferable that portions of the fixed charge film 13 and the insulation film 30 constituting the first insulation film 25, the portions being formed on the back surface Sb, have film thicknesses of approximately 60 nm and approximately 100 nm, respectively.

According to the example depicted in FIG. 25 herein, as a transition depicted from FIG. 25B to FIG. 25C, after the similar heat expansion material 29 is formed, the similar heat expansion material 29 is removed by etching. Specifically, the similar heat expansion material 29 other than the portion formed on the trench is removed by etching.

However, when this etching was actually carried out, it was confirmed that scatters cut by etching, such as metal, adhere to the semiconductor wafer or an interior of a device chamber. Such adhesion of the metal scatters may cause and lower an etching rate and an ashing rate due to metal contamination inside the device.

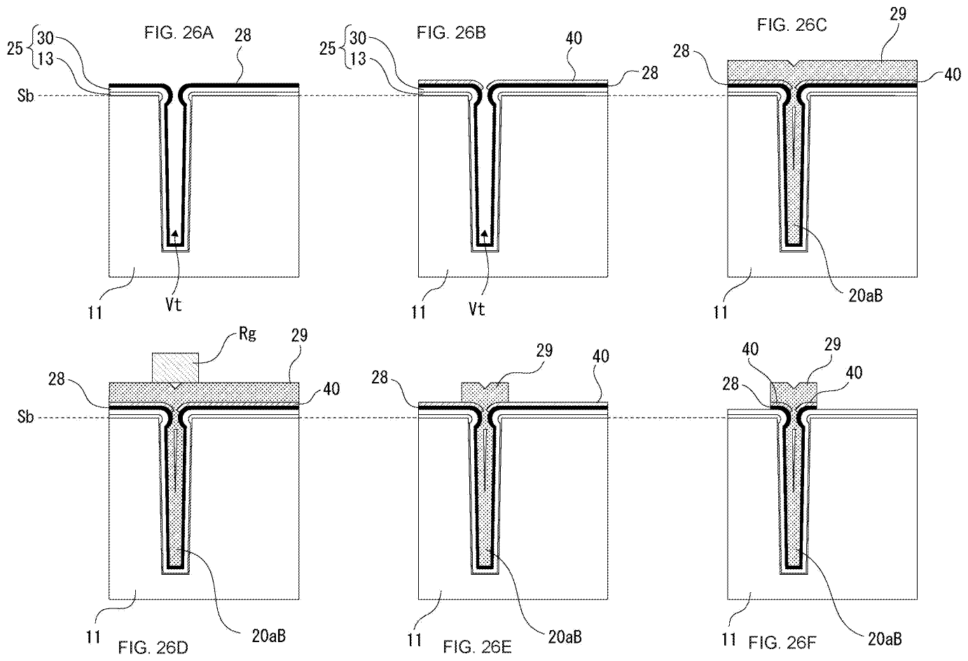

In view of this, proposed is such a method which forms a stopper film 40 on the metal film 28 before the similar heat expansion material 29 is formed, as depicted in FIG. 26.

First, as depicted in FIG. 26A, for the semiconductor substrate 11 having the vertical groove Vt, the fixed charge film 13 is formed on the side wall portion of the vertical groove Vt and the back surface Sb of the semiconductor substrate 11 in this case as well, as in the case of FIG. 25A described above. The insulation film 30 is then formed on the fixed charge film 13. Thereafter, the metal film 28 is formed on the insulation film 30.

Subsequently, as depicted in FIG. 26B, the stopper film 40 including SiN (silicon nitride) is formed on the metal film 28. At this time, it is preferable that the stopper film 40 have a film pressure of 80 nm or larger. It has been confirmed that the film thickness of 80 nm or larger sufficiently protects the metal film 28 from processing variations produced by etching of the similar heat expansion material 29 described below.

Note herein that SiN has poor embeddability. Accordingly, the stopper film 40 is not formed in the vertical groove Vt (i.e., in the trench) as depicted in the figure. At this time, a portion of the metal film 28 on the vertical groove Vt near the back surface Sb is formed to have a rounded shape in a cross-sectional view as depicted in the figure. The portion of the stopper film 40 on the vertical groove Vt near the back surface Sb is formed along this rounded portion. Accordingly, the stopper film 40 is formed in such a manner as to achieve substantial closure of the vertical groove Vt as depicted in the figure.

After the stopper film 40 is formed, the similar heat expansion material 29 (e.g., silicon) is formed on the stopper film 40 as depicted in FIG. 26C. In this manner, the similar heat expansion material 29 is embedded inside the metal film 28 in the vertical groove Vt to obtain a structure of the trench 20aB.

At this time, the similar heat expansion material 29 is formed on the trench 20aB and also on the stopper film 40 formed on the upper layer of the back surface Sb of the semiconductor substrate 11.

After the similar heat expansion material 29 is formed, the resist Rg is patterned and exposed only on the upper part of the trench 20aB as depicted in FIG. 26D, and the similar heat expansion material 29 is removed by an etching step as depicted in FIG. 26E. At this time, the similar heat expansion material 29 remains on the upper part of the trench 20aB.

After completion of the etching step in FIG. 26E, a process for removing the stopper film 40 and the metal film 28 other than those on the upper part of the trench 20aB is performed as depicted in FIG. 26F.

The manufacturing method described above can prevent scatters such as metal produced during etching of the similar heat expansion material 29, thereby preventing lowering of the etching rate and the ashing rate.

Moreover, the manufacturing method described above can reduce a film pressure of the similar heat expansion material 29 during formation of the similar heat expansion material 29, according to formation of the stopper film 40. Accordingly, shortening of a process lead time is achievable.

Further, the manufacturing method described above can improve closure of the trench 20aB by formation of the stopper film 40.

Note that the manufacturing method depicted in FIG. 26 may form a film of SiO (silicon oxide) constituting the similar heat expansion material 29, by using ALD, for example, in the film forming step of the similar heat expansion material 29 depicted in FIG. 26C. In this manner, an inorganic film can be formed on the metal film 28 in the trench 20aB. Accordingly, reduction of migration of the metal film 28 is achievable.

According to the third embodiment herein, particularly in a case of use of liquid silicon as described above, for example, a material to which a conductive material such as carbon black has been added can be used as the similar heat expansion material 29.

In this manner, the portion constituted by the similar heat expansion material 29 in the trench 20aB is available as an electrode.

### 4. Fourth Embodiment

A fourth embodiment prevents, in a case where a trench which is of a type including the vertical groove Vt inside of which is filled with metal is adopted, crack generation caused by a void produced in a metal portion in the trench.

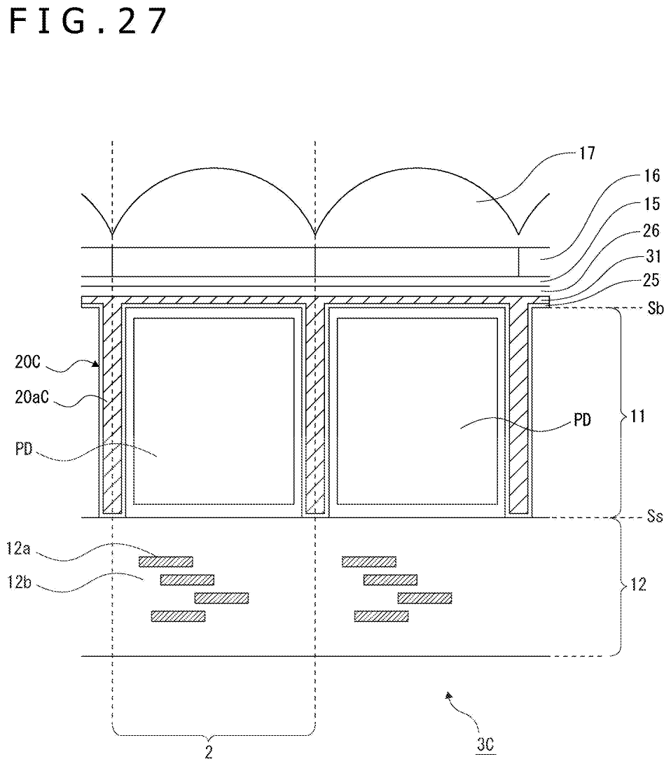

FIG. 27 is a cross-sectional diagram for explaining a schematic structure of a pixel array unit 3C according to the third embodiment.

The pixel array unit 3C is different from the pixel array unit 3 in the first embodiment in a point that a pixel separation portion 20C is formed in place of the pixel separation portion 20. In other words, a trench 20aC is formed in place of the trench 20a.

The trench 20aC has the first insulation film 25 in an outermost peripheral portion. As depicted in the figure, the first insulation film 25 is continuously formed from the outermost peripheral portion of the trench 20aB to an upper part of the back surface Sb of the semiconductor substrate 11.

In addition, the inside of the first insulation film 25 in the trench 20aC is filled with a light shielding film 31 including metal. As depicted in the figure, the light shielding film 31 is continuously formed from the inside of the first insulation film 25 in the trench 20aC to a portion on the first insulation film 25 above the back surface Sb of the semiconductor substrate 11.

While not depicted in the figure, a portion that is included in the light shielding film 31 and that constitutes an upper layer of the back surface Sb of the semiconductor substrate 11 is formed in such a manner as to have an opening at a portion above the photodiode PD for each of the pixels 2.

Moreover, the pixel array unit 3C has the second insulation film 26 formed on the light shielding film 31. Note that the second insulation film 26 is formed not only on the light shielding film 31 but also on the first insulation film 25 below the above-mentioned opening of the light shielding film 31.

In this case, similarly to above, each of a structure in an upper layer portion with respect to the second insulation film 26 and a structure in a lower layer portion with respect to the semiconductor substrate 11 is similar to the corresponding structure in the case of the pixel array unit 3, and therefore is not repeatedly explained.

For achieving embedding of metal into the trench in a preferable manner herein, various improvements such as an increase in wettability at a portion along the side wall of the vertical groove Vt are required. However, no specific methods for achieving embedding of metal into the trench in a preferable manner has been proposed.

The inventors of the present application attempted embedding of metal into the trench by the following method. Specifically, a TiN film is formed on the side wall portion of the vertical groove Vt by CVD or ALD as a first base layer for metal embedding. In addition, a TiAl film is formed by ALD as a second base layer, and an Al film is formed on this second base layer by CVD as a metal film.

However, it was confirmed that this method for embedding metal generates a large number of voids in the metal embedded.

When a large number of voids are generated in the metal embedded in the trench as in such a case, a crack is easily produced in the semiconductor substrate 11 according to generation of these voids.

Accordingly, the present embodiment proposes the following method as a method for embedding metal in the trench.

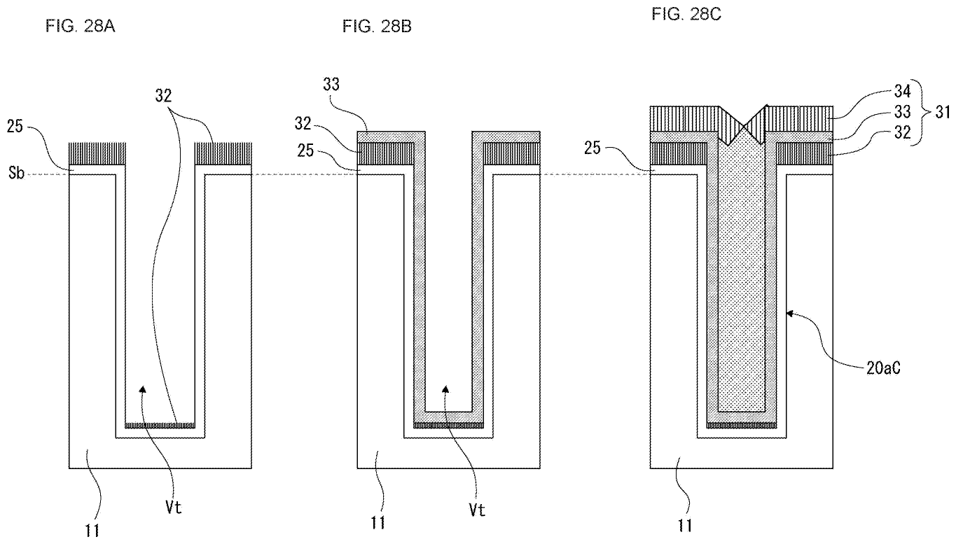

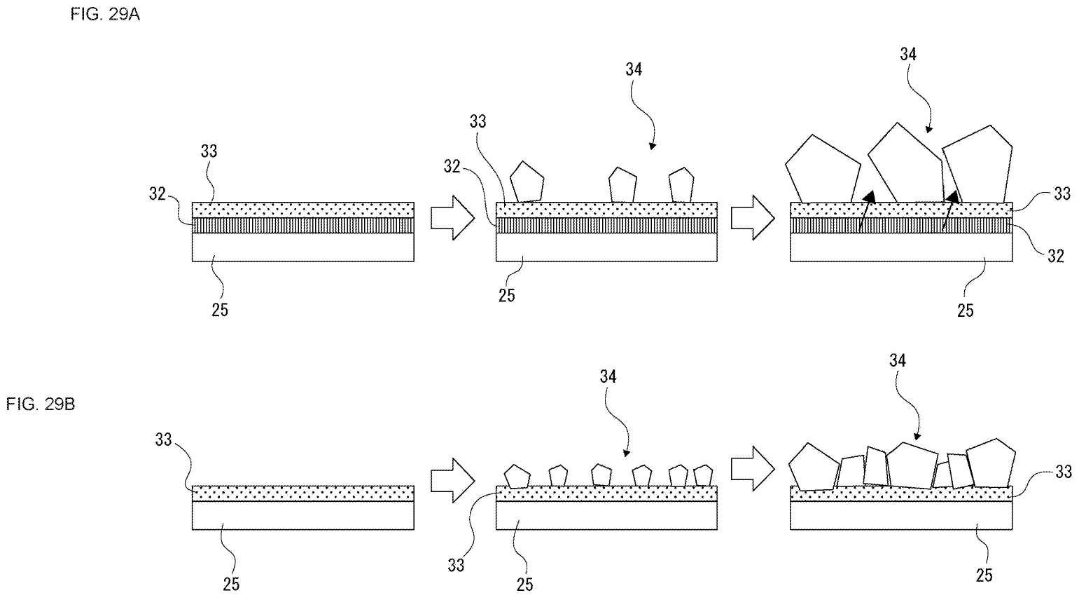

FIG. 28 is an explanatory diagram depicting a manufacturing method of the sensor device 1 according to the fourth embodiment. Particularly described herein will be a step associated with embedding of metal in the trench.

First, the first insulation film 25 and a barrier metal film 32 are formed on a target which is the semiconductor substrate 11 where the vertical groove Vt is engraved from the back surface Sb side (FIG. 28A). Specifically, the first insulation film 25 is first formed by a film forming process such as ALD, for example, on a target which is the back surface Sb of the semiconductor substrate 11 where the vertical groove Vt is formed. In this manner, the first insulation film 25 is formed on the back surface Sb of the semiconductor substrate 11 and the side wall portion of the vertical groove Vt. According to the present example, the first insulation film 25 includes SiO₂.

Thereafter, the barrier metal film 32 is formed on the first insulation film 25 by directional sputtering. The barrier metal film 32 formed by directional sputtering is chiefly provided on the first insulation film 25 formed on the back surface Sb, but substantially none of the barrier metal film 32 is provided on a portion of the first insulation film 25 located along the side wall portion of the vertical groove Vt. Note that the barrier metal film 32 is formed on a portion of the first insulation film 25 located along the bottom surface of the vertical groove Vt, in a case where the vertical groove Vt has a relatively small depth. However, substantially none of the barrier metal film 32 is formed thereon in a case where the vertical groove Vt has a large depth.

According to the present example, the barrier metal film 32 includes Ti.

Directivity of directional sputtering herein is adjustable according to factors such as a degree of ionization, a level of stage bias, an application distance of film forming gas, and collimation.

After the barrier metal film 32 is formed, a wetting film 33 is formed (FIG. 28B). Specifically, the wetting film 33 is formed by a film forming process such as CVD and ALD, for example, on a target which is the back surface Sb side of the semiconductor substrate 11 where the barrier metal film 32 is formed. In this manner, the wetting film 33 is formed in such a manner as to be laminated on a portion of the first insulation film 25 located along the side wall portion of the vertical groove Vt and a portion of the barrier metal film 32 located along the back surface Sb.

According to the present example, the wetting film 33 includes TiAl.

After the wetting film 33 is formed in the manner described above, a metal film 34 is formed by a film forming process such as CVD and ALD, for example, on the wetting film 33 (FIG. 28C). As depicted in the figure, the metal film 34 is continuously formed from the inside of a portion of the wetting film 33 located along the side wall portion of the vertical groove Vt to an upper part of a portion of the wetting film 33 located along the back surface Sb.

According to the present example, the metal film 34 includes Al.

The light shielding film 31 depicted in FIG. 27 is a film which includes the barrier metal film 32, the wetting film 33, and the metal film 34 formed in the manner described above.

According to the present example herein, the barrier metal film 32 is formed by directional sputtering. In this case, substantially none of the barrier metal film 32 is formed in a portion along the side wall portion of the vertical groove Vt. On the other hand, the barrier metal film 32 having a certain film thickness is formed in a portion of the semiconductor substrate 11 located along the back surface Sb.

Accordingly, the wetting film 33 at the portion along the side wall portion of the vertical groove Vt, i.e., inside the trench 20aC, becomes amorphous or microcrystalline. On the other hand, a portion of the wetting film 33 located along the back surface Sb, i.e., a portion of the wetting film 33 on the first insulation film 25 outside the trench 20aC, has highly oriented crystals.

It is estimated that this state is produced for the following reason. Substantially none of the barrier metal film 32 is formed on the portion along the side wall portion of the vertical groove Vt, and therefore, substantially no crystal orientation improvement effect is offered at this portion along the side wall portion. Meanwhile, the barrier metal film 32 having a certain film thickness is formed at the portion along the back surface Sb, and therefore, improvement of crystal orientation is achieved at the portion along the back surface Sb.

As described above, the wetting film 33 becomes amorphous or microcrystalline inside the trench 20aC. Accordingly, the metal film 34 formed inside the portion of the wetting film 33 located in the trench 20aC also becomes amorphous or microcrystalline. The amorphous or microcrystalline state of the metal film 34 achieved in such a manner reduces void generation in the metal film 34 in the trench.

Accordingly, prevention of crack generation caused by voids generated in the metal film 34 in the trench is achievable. Specifically, generation of a crack caused by these voids according to heat treatment of the manufacturing process of the sensor device is avoidable.

Moreover, the wetting film 33 has highly oriented crystals at the portion along the back surface Sb outside the trench 20aC. In this case, the portion of the metal film 34 located along the back surface Sb also has highly oriented crystals. In the highly oriented crystal state thus achieved, the portion of the metal film 34 located along the back surface Sb has a uniform film thickness, and therefore improves performance of the function as the light shielding film.

Described with reference to FIG. 29 will be a difference in film formation mode of the metal film 34 between a case where the barrier metal film 32 is present and a case where the barrier metal film 32 is absent.

FIG. 29A schematically depicts a film formation mode of the metal film 34 in a case where the barrier metal film 32 is present as a base layer, while FIG. 29B schematically depicts a film formation mode of the metal film 34 in a case where the barrier metal film 32 as a base layer is absent. In addition, FIG. 29A and FIG. 29B each depict progress in film formation of the metal film 34 from the right side to the left side in the figure.

In the case of FIG. 29A where the barrier metal film 32 is present, the wetting film 33 is in a crystal mixed state by an effect of the barrier metal film 32 formed in the lower layer. Accordingly, in an initial film formation stage of the metal film 34 on the wetting film 33, partial priority of metal crystals is caused on the wetting film 33 as depicted in a central part of the figure. With further growth of crystals in the progress in film formation of the metal film 34, clearances are produced between crystals due to such partial priority of crystals, as indicated by arrows in a right part of the figure. These clearances generate voids in the metal film 34.

Meanwhile, in the case of FIG. 29B where the barrier metal film 32 is absent, the wetting film 33 comes into an amorphous or microcrystalline state since the barrier metal film 32 is absent in the lower layer. In an initial film formation stage of the metal film 34 on the wetting film 33 in such a state, nucleation is caused on the entire wetting film 33 as depicted in a central part of the figure. With progress in film formation of the metal film 34 from the state of entire nucleation, clearances are not easily produced as depicted in a right part of the figure. Accordingly, generation of voids in the metal film 34 is reduced.

While Ni is adopted herein as the barrier metal film 32 in the above case, TiN, Ta, TaN, W, WN, or the like can be used as the material of the barrier metal film 32, for example.

Moreover, the wetting film 33 may be not only a film including TiAl presented by way of example but also a single film or a nitride film of CoAl, RuAl, NbAl, Co, Ru, Nb, W, or Ti, or a laminated film combining two or more types of these materials, for example.

Further, as the metal film 34, not only Al presented by way of example but also Cu or the like can be used, for example.

### 5. Modification

Note that embodiments are not limited to the specific examples described above and can include configurations constituting various modifications.

For example, each of the method for forming the pixel separation portion in directions different from cleavage directions and the method for forming the metal film 22 on the trench as described in the first embodiment can be combined with the second embodiment, the third embodiment, and the fourth embodiment.

Moreover, while the example described above is the example of the present technology applied to an image sensor, i.e., a sensor device which forms an image indicating, as a sensing image, light quantities received by each of the pixels 2, the present technology is also appropriately applicable to a depth sensor which forms a depth image (an image indicating distances from each of the pixels 2) as a sensing image, such as a ToF sensor, for example.

Further, the present technology is also appropriately applicable to a sensor device which includes an organic material constituting a photoelectric conversion element (e.g., see PCT Patent Publication No. WO2020/255999), a sensor device which includes an SPAD (Single Photon Avalanche Diode) constituting a photoelectric conversion element (e.g., see PCT Patent Publication No. WO2020/203222), and others.

The present technology is applicable to a wide variety of sensor devices each having a semiconductor substrate which includes a plurality of photoelectric conversion elements arranged for each pixel and a pixel separation portion having a trench formed between pixels to separate the pixels.

### 6. Summary of Embodiments

As described above, a sensor device (sensor device 1) according to the first embodiment includes a semiconductor substrate (semiconductor substrate 11) that includes a plurality of photoelectric conversion elements (photodiodes PD) arranged for each pixel (pixel 2) and a pixel separation portion (pixel separation portion 20) having a trench (trench 20a) formed between pixels to separate the pixels. The pixel separation portion of the semiconductor substrate is formed in directions different from cleavage directions of crystals of the semiconductor substrate.

The pixel separation portion formed in directions different from the cleavage directions as described above prevents easy crack generation in the semiconductor substrate along the trench of the pixel separation portion.

Accordingly, prevention of crack generation in the semiconductor substrate is achievable.

In addition, according to the sensor device of the first embodiment, the semiconductor substrate is a silicon substrate, and the pixel separation portion is formed in directions different from cleavage directions [01⁻1], [011⁻], [011], [01⁻1⁻], [1⁻01], [101⁻], [101], [1⁻01⁻], [1⁻10], [11⁻0], [110], and [1⁻1⁻0] of silicon crystals.

This configuration prevents easy crack generation in the semiconductor substrate along the trench of the pixel separation portion.

Accordingly, prevention of crack generation in the semiconductor substrate is achievable.

In addition, according to the sensor device of the first embodiment, the pixel separation portion is formed in crystal directions [001], [001⁻], [01⁻0], and of the semiconductor substrate.

In this case, the trench of the pixel separation portion is formed in directions shifted from the cleavage directions by 45 degrees.

Accordingly, an effect of crack generation prevention can be maximized from a viewpoint of a relation between the forming directions of the trench and the cleavage directions.

In addition, according to the sensor device of the first embodiment, the trench is formed in the semiconductor substrate along outermost peripheral sides of a pixel arrangement region (pixel arrangement region Ap) that is a region where the plurality of pixels is two-dimensionally arranged.

In a case where the trench is formed only in the pixel separation portion, i.e., in a case where the trench is formed only in the boundary portions between the pixels, the trench is discontinued at positions of the outermost peripheral sides of the pixel arrangement region. Accordingly, a crack is easily generated from these discontinued portions. The configuration which includes the trench along the outermost peripheral sides of the pixel arrangement region as described above eliminates the foregoing discontinued portions.

Accordingly, prevention of crack generation from the outermost peripheral portion of the pixel arrangement region is achievable.

In addition, according to the sensor device of the first embodiment, the trench formed along the outermost peripheral sides of the pixel arrangement region has a chamfered shape at each of portions constituting four corners of the pixel arrangement region.

A crack is more easily generated from the four corners of the pixel arrangement region as the bending angles of the portions constituting the four corners approaches 90 degrees for the trench formed on the outermost peripheral sides of the pixel arrangement region.

The configuration in which the trench has a chamfered shape for each of the portions of the four corners of the pixel arrangement region as described above can reduce crack generation from these portions of the four corners.

In addition, according to the sensor device of the first embodiment, a metal film that covers an upper part of the trench formed along the outermost peripheral sides of the pixel arrangement region is formed.

This configuration prevents crack generation from the outermost peripheral portion of the pixel arrangement region.

In addition, according to the sensor device of the first embodiment, a metal film (portion 22b) is formed outside the pixel arrangement region in the cleavage directions of the semiconductor substrate.

This configuration prevents crack generation in oblique directions from the four corners of the trench formed along the outermost peripheral sides of the pixel arrangement region.

A sensor device (sensor device 1) according to the second embodiment includes a semiconductor substrate that includes a plurality of photoelectric conversion elements arranged for each pixel and a pixel separation portion (pixel separation portion 20A) having a trench (trench 20aA) formed between pixels to separate the pixels. The sensor device further includes a first insulation film (first insulation film 25) formed on a first surface that is one of two surfaces crossing a thickness direction of the semiconductor substrate at right angles and that corresponds to a surface where the trench is engraved and on an outermost peripheral portion of the trench, and a second insulation film (second insulation film 26) formed on the first insulation film. The first insulation film is formed such that the trench has an opening (opening Ot) on a first surface side. The second insulation film is formed across the opening of the trench.

The configuration which includes the first insulation film formed such that the trench has the opening on the first surface side as described above prevents contact between portions of the first insulation film in the trench in a sensor device manufacturing process.

Accordingly, this configuration achieves prevention of crack generation in the semiconductor substrate caused by contact between portions of the first insulation film in the trench in the sensor device manufacturing process. The second insulation film herein is formed across the opening of the trench. This configuration prevents closure of the opening caused by formation of the second insulation film after formation of the first insulation film.

In addition, according to the sensor device of the second embodiment, a resin film (resin film 27) that covers an upper part of the opening is formed between the first insulation film and the second insulation film.

The structure described above is produced by forming the first insulation film, subsequently patterning a resist covering an upper part of the opening of the trench, and then forming the second insulation film.

Accordingly, formation of the second insulation film inside the first insulation film in the trench is prevented, and a cavity can be formed inside the first insulation film in the trench. The cavity thus formed can reduce stress produced by a heat shrink generated in the first insulation film in the trench according to heat treatment during the sensor device manufacture. Accordingly, prevention of crack generation from the trench is achievable.

A manufacturing method according to the second embodiment includes a first film forming step of forming a first insulation film on a first surface that is one of two surfaces crossing a thickness direction of a semiconductor substrate at right angles and that corresponds to a surface where a vertical groove (vertical groove Vt) is engraved and on a side wall portion of the vertical groove, the semiconductor substrate being a substrate where a plurality of photoelectric conversion elements is arranged for each pixel and including the vertical groove separating the pixels, and a second film forming step of forming a second insulation film on the first insulation film. The first film forming step forms the first insulation film such that the vertical groove has an opening on a first surface side. The second film forming step forms the second insulation film across an upper part of the opening of the vertical groove.

This method prevents contact between portions of the first insulation film formed on the side wall portion of the vertical groove for pixel separation in the sensor device manufacturing process.

Accordingly, this method achieves prevention of crack generation in the semiconductor substrate caused by contact between portions of the first insulation film formed on the side wall portion of the vertical groove for pixel separation in the sensor device manufacturing process. The second insulation film herein is formed across the upper part of the opening of the vertical groove. This configuration prevents closure of the opening caused by formation of the second insulation film after formation of the first insulation film.

In addition, according to the manufacturing method of the second embodiment, the second film forming step forms the second insulation film after resist patterning is performed for a target which is the upper part of the opening.

In this manner, the second insulation film is formed across the opening of the vertical groove.

Accordingly, formation of the second insulation film inside the first insulation film in the vertical groove is prevented, and a cavity can be formed inside the first insulation film in the vertical groove. The cavity thus formed can reduce stress produced by a heat shrink generated in the first insulation film in the trench according to heat treatment during the sensor device manufacture. Accordingly, prevention of crack generation from the trench is achievable.

In addition, according to the manufacturing method of the second embodiment, the first film forming step forms the first insulation film by atomic layer deposition, and the second film forming step forms the second insulation film by chemical vapor deposition.

The first insulation film can be formed such that the vertical groove has the opening on the first surface side, by using atomic layer deposition (ALD) for forming the first insulation film. Moreover, a material of the second insulation film does not easily enter the opening of the vertical groove, by using chemical vapor deposition (CDV) for forming the second insulation film.

Accordingly, this method achieves prevention of crack generation in the semiconductor substrate caused by contact between portions of the first insulation film formed on the side wall portion of the vertical groove for pixel separation in the sensor device manufacturing process. Moreover, the second insulation film formed across the upper part of the opening of the vertical groove prevents closure of the opening caused by formation of the second insulation film.

In addition, according to the manufacturing method of the second embodiment, the first film forming step forms the first insulation film by atomic layer deposition, and the second film forming step forms the second insulation film by atomic layer deposition that has a higher film forming temperature than a film forming temperature of the first insulation film.

The first insulation film can be formed such that the vertical groove has the opening on the first surface side, by using atomic layer deposition (ALD) for forming the first insulation film. Moreover, the material of the second insulation film does not easily enter the opening of the vertical groove, by using atomic layer deposition that has a higher film forming temperature to form the second insulation film than the film forming temperature of the first insulation film.

Accordingly, this method achieves prevention of crack generation in the semiconductor substrate caused by contact between portions of the first insulation film formed on the side wall portion of the vertical groove for pixel separation in the sensor device manufacturing process. Moreover, the second insulation film formed across the upper part of the opening of the vertical groove prevents closure of the opening caused by formation of the second insulation film.

Further, film formation of both the first and second insulation films can be achieved by using a film forming device for atomic layer deposition. In this case, a necessity of switching a device for film formation for each of the first and second insulation films is eliminated. Accordingly, a work load associated with manufacture of the sensor device can be reduced.

A sensor device (sensor device 1) according to the third embodiment includes a semiconductor substrate that includes a plurality of photoelectric conversion elements arranged for each pixel and a pixel separation portion (pixel separation portion 20B) having a trench (trench 20aB) formed between pixels to separate the pixels. An insulation film is formed at an outermost peripheral portion of the trench. A metal film is formed inside the insulation film. A similar heat expansion material that has a heat expansion characteristic similar to a heat expansion characteristic of a material constituting the semiconductor substrate is embedded inside the metal film.

As described above, the similar heat expansion material for the material constituting the semiconductor substrate is embedded inside the metal film in the trench. Accordingly, even if a heat shrink is caused by heat treatment during manufacture of the sensor device, the degrees of the heat shrink outside the trench and inside the trench are equalized. This configuration can reduce stress produced at an entrance portion of the trench according to the heat treatment described above.

Accordingly, this configuration achieves prevention of crack generation caused by stress produced at the entrance portion of the trench according to heat treatment of the sensor device manufacturing process, while improving the light collection performance for the photoelectric conversion element with use of the metal film formed inside the trench.

In addition, according to the sensor device of the third embodiment, the semiconductor substrate is a silicon substrate, and the similar heat expansion material is silicon.

This configuration reduces stress produced at the entrance portion of the trench according to heat treatment during manufacture of the sensor device, in a case where the semiconductor substrate is silicon substrate.

Specifically, in the case where the semiconductor substrate is a silicon substrate, this configuration achieves prevention of crack generation caused by stress produced at the entrance portion of the trench according to heat treatment of the sensor device manufacturing process, while improving the light collection performance for the photoelectric conversion element with use of the metal film formed inside the trench.

In addition, according to the sensor device of the third embodiment, the similar heat expansion material is polysilicon or amorphous silicon.

This configuration reduces stress produced at the entrance portion of the trench according to heat treatment during manufacture of the sensor device, in a case where the semiconductor substrate is silicon substrate.

Specifically, in the case where the semiconductor substrate is a silicon substrate, this configuration achieves prevention of crack generation caused by stress produced at the entrance portion of the trench according to heat treatment of the sensor device manufacturing process, while improving the light collection performance for the photoelectric conversion element with use of the metal film formed inside the trench.

In addition, according to the sensor device of the third embodiment, the similar heat expansion material is a material to which a conductive material is added.

In this manner, the portion constituted by the similar heat expansion material in the trench is available as an electrode.

A sensor device according to the fourth embodiment includes a semiconductor substrate that includes a plurality of photoelectric conversion elements arranged for each pixel and a pixel separation portion having a trench (trench 20aC) formed between pixels to separate the pixels. The sensor device further includes an insulation film (first insulation film 25) formed on a first surface that is one of two surfaces crossing a thickness direction of the semiconductor substrate at right angles and that corresponds to a surface where the trench is engraved and on an outermost peripheral portion of the trench, a wetting film (wetting film 33) formed on the insulation film, and a metal film (metal film 34) formed on the wetting film. The wetting film becomes amorphous or microcrystalline on the insulation film in the trench and has highly oriented crystals on the insulation film outside the trench.

The configuration including the wetting film which is provided for forming the metal film in the trench and becomes amorphous or microcrystalline on the insulation film in the trench as described above can reduce generation of voids in the metal film in the trench.

Accordingly, generation of a crack caused by voids generated in the metal film according to heat treatment of the sensor device manufacturing process is avoidable. Moreover, the wetting film which has highly oriented crystals on the insulation film outside the trench can equalize a film thickness of the metal film at a portion extending in a substrate surface direction and improve performance as a light shielding film.

In addition, according to the sensor device of the fourth embodiment, the wetting film includes TiAl.

This configuration offers preferable wettability in a case where a barrier metal film includes a Ti-based material.

In addition, according to the sensor device of the fourth embodiment, the metal film includes Al.

Al is suited for a material of a reflection film.

Accordingly, this configuration improves a pixel-to-pixel light leakage reduction effect and light collection performance for the photoelectric conversion elements of the pixel separation portion including the metal film in the trench.

A manufacturing method according to the fourth embodiment includes a film forming step of forming an insulation film on a first surface that is one of two surfaces crossing a thickness direction of a semiconductor substrate at right angles and that corresponds to a surface where a vertical groove is engraved and on a side wall portion of the vertical groove, the semiconductor substrate being a substrate where a plurality of photoelectric conversion elements is arranged for each pixel and including the vertical groove separating the pixels, a barrier metal film forming step of forming a barrier metal film on the insulation film by directional sputtering, a wetting film forming step of forming a wetting film on the barrier metal film, and a metal film forming step of forming a metal film on the wetting film.

According to the method which forms the barrier metal film by directional sputtering as described above, the wetting film is allowed to become amorphous or microcrystalline on the insulation film in the trench and have highly oriented crystals on the insulation film outside the trench.

In the state where the wetting film is amorphous or microcrystalline on the insulation film in the trench, voids are not easily generated in the metal film in the trench. Accordingly, generation of a crack caused by voids generated in the metal film according to heat treatment of the sensor device manufacturing process is avoidable. Moreover, the wetting film which has highly oriented crystals on the insulation film outside the trench equalizes a film thickness of the metal film at the portion extending in a substrate surface direction and improves performance as a reflection film.

Note that advantageous effects described in the present description are presented only by way of example and that advantageous effects to be offered are not limited to those. In addition, other advantageous effects may be produced.

### 7. Present Technology

The present technology can also adopt the following configurations.

(1)

A sensor device including:
a semiconductor substrate that includes a plurality of photoelectric conversion elements arranged for each pixel and a pixel separation portion having a trench formed between pixels to separate the pixels, in which
the pixel separation portion of the semiconductor substrate is formed in directions different from cleavage directions of crystals of the semiconductor substrate.
   (2)

The sensor device according to (1), in which
the semiconductor substrate is a silicon substrate, and
the pixel separation portion is formed in directions different from cleavage directions [01⁻1], [011⁻], [011], [01⁻1⁻], [1⁻01], [101⁻], [101], [1⁻01⁻], [1⁻10], [11⁻0], [110], and [1⁻1⁻0] of silicon crystals.
   (3)

The sensor device according to (2), in which the pixel separation portion is formed in crystal directions [001], [001⁻], [01⁻0], and of the semiconductor substrate.

(4)

The sensor device according to any one of (1) to (3), in which
the trench is formed in the semiconductor substrate along outermost peripheral sides of a pixel arrangement region that is a region where a plurality of the pixels is two-dimensionally arranged.
   (5)

The sensor device according to (4), in which
the trench formed along the outermost peripheral sides of the pixel arrangement region has a chamfered shape at each of portions constituting four corners of the pixel arrangement region.
   (6)

The sensor device according to (4) or (5), in which
a metal film that covers an upper part of the trench formed along the outermost peripheral sides of the pixel arrangement region is formed.
   (7)

The sensor device according to any one of (4) to (6), in which
a metal film is formed outside the pixel arrangement region in the cleavage directions of the semiconductor substrate.
   (8)

A sensor device including:
a semiconductor substrate that includes a plurality of photoelectric conversion elements arranged for each pixel and a pixel separation portion having a trench formed between pixels to separate the pixels;
a first insulation film formed on a first surface that is one of two surfaces crossing a thickness direction of the semiconductor substrate at right angles and that corresponds to a surface where the trench is engraved and on an outermost peripheral portion of the trench; and
a second insulation film formed on the first insulation film, in which
the first insulation film is formed such that the trench has an opening on a first surface side, and
the second insulation film is formed across an upper part of the opening of the trench.
   (9)

The sensor device according to (8), in which
a resin film that covers the upper part of the opening is formed between the first insulation film and the second insulation film.
   (10)

A manufacturing method including:
a first film forming step of forming a first insulation film on a first surface that is one of two surfaces crossing a thickness direction of a semiconductor substrate at right angles and that corresponds to a surface where a vertical groove is engraved and on a side wall portion of the vertical groove, the semiconductor substrate being a substrate where a plurality of photoelectric conversion elements is arranged for each pixel and including the vertical groove separating the pixels; and
a second film forming step of forming a second insulation film on the first insulation film, in which
the first film forming step forms the first insulation film such that the vertical groove has an opening on a first surface side, and the second film forming step forms the second insulation film across an upper part of the opening of the vertical groove.
   (11)

The manufacturing method according to (10), in which
the second film forming step forms the second insulation film after resist patterning is performed for a target that is the upper part of the opening.
   (12)

The manufacturing method according to (10), in which
the first film forming step forms the first insulation film by atomic layer deposition, and
the second film forming step forms the second insulation film by chemical vapor deposition.
   (13)

The manufacturing method according to (10), in which
the first film forming step forms the first insulation film by atomic layer deposition, and
the second film forming step forms the second insulation film by atomic layer deposition that has a higher film forming temperature than a film forming temperature of the first insulation film.
   (14)

A sensor device including:
a semiconductor substrate that includes a plurality of photoelectric conversion elements arranged for each pixel and a pixel separation portion having a trench formed between pixels to separate the pixels, in which
an insulation film is formed at an outermost peripheral portion of the trench,
a metal film is formed inside the insulation film, and
a similar heat expansion material that has a heat expansion characteristic similar to a heat expansion characteristic of a material constituting the semiconductor substrate is embedded inside the metal film.
   (15)

The sensor device according to (14), in which
the semiconductor substrate is a silicon substrate, and
the similar heat expansion material is silicon.
   (16)

The sensor device according to (15), in which
the similar heat expansion material is polysilicon or amorphous silicon.
   (17)

The sensor device according to any one of (14) to (16), in which
the similar heat expansion material is a material to which a conductive material is added.
   (18)

A sensor device including:
a semiconductor substrate that includes a plurality of photoelectric conversion elements arranged for each pixel and a pixel separation portion having a trench formed between pixels to separate the pixels;
an insulation film formed on a first surface that is one of two surfaces crossing a thickness direction of the semiconductor substrate at right angles and that corresponds to a surface where the trench is engraved and on an outermost peripheral portion of the trench;
a wetting film formed on the insulation film; and
a metal film formed on the wetting film, in which
the wetting film becomes amorphous or microcrystalline on the insulation film in the trench and has highly oriented crystals on the insulation film outside the trench.
   (19)

The sensor device according to (18), in which
the wetting film includes TiAl.
   (20)

The sensor device according to (18) or (19), in which
the metal film includes Al.

### REFERENCE SIGNS LIST

1: Sensor device
2: Pixel
3, 3A, 3B, 3C: Pixel array unit
PD: Photodiode
11: Semiconductor substrate
12: Wiring layer
12a: Wire
12b: Interlayer dielectric
13: Fixed charge film
14: Insulation film
15: Flattening film
16: Filter layer
17: Micro-lens
20, 20A, 20B, 20C: Pixel separation portion
20a, 20aA, 20aB, 20aC: Trench
21: Pixel light shielding portion
Ap: Pixel arrangement region
22: Metal film
25: First insulation film
26: Second insulation film
27: Resin film
Ot: Opening
Vt: Vertical groove
Rg: Resist
28: Metal film
29: Similar heat expansion material
30: Insulation film
31: Light shielding film
32: Barrier metal film
33: Wetting film
34: Metal film
40: Stopper film

1. A sensor device comprising:
a semiconductor substrate that includes a plurality of photoelectric conversion elements arranged for each pixel and a pixel separation portion having a trench formed between pixels to separate the pixels, wherein
the pixel separation portion of the semiconductor substrate is formed in directions different from cleavage directions of crystals of the semiconductor substrate.

2. The sensor device according to claim 1, wherein
the semiconductor substrate is a silicon substrate, and
the pixel separation portion is formed in directions different from cleavage directions [01⁻1], [011⁻], [011], [01⁻1⁻], [1⁻01], [101⁻], [101], [1⁻01⁻], [1⁻10], [11⁻0], [110], and [1⁻1⁻0] of silicon crystals.

3. The sensor device according to claim 2, wherein
the pixel separation portion is formed in crystal directions [001], [001⁻], [01⁻0], and of the semiconductor substrate.

4. The sensor device according to claim 1, wherein
the trench is formed in the semiconductor substrate along outermost peripheral sides of a pixel arrangement region that is a region where a plurality of the pixels is two-dimensionally arranged.

5. The sensor device according to claim 4, wherein
the trench formed along the outermost peripheral sides of the pixel arrangement region has a chamfered shape at each of portions constituting four corners of the pixel arrangement region.

6. The sensor device according to claim 4, wherein
a metal film that covers an upper part of the trench formed along the outermost peripheral sides of the pixel arrangement region is formed.

7. The sensor device according to claim 4, wherein
a metal film is formed outside the pixel arrangement region in the cleavage directions of the semiconductor substrate.

8. A sensor device comprising:
a semiconductor substrate that includes a plurality of photoelectric conversion elements arranged for each pixel and a pixel separation portion having a trench formed between pixels to separate the pixels;
a first insulation film formed on a first surface that is one of two surfaces crossing a thickness direction of the semiconductor substrate at right angles and that corresponds to a surface where the trench is engraved and on an outermost peripheral portion of the trench; and
a second insulation film formed on the first insulation film, wherein
the first insulation film is formed such that the trench has an opening on a first surface side, and
the second insulation film is formed across an upper part of the opening of the trench.

9. The sensor device according to claim 8, wherein
a resin film that covers the upper part of the opening is formed between the first insulation film and the second insulation film.

10. A manufacturing method comprising:
a first film forming step of forming a first insulation film on a first surface that is one of two surfaces crossing a thickness direction of a semiconductor substrate at right angles and that corresponds to a surface where a vertical groove is engraved and on a side wall portion of the vertical groove, the semiconductor substrate being a substrate where a plurality of photoelectric conversion elements is arranged for each pixel and including the vertical groove separating the pixels; and
a second film forming step of forming a second insulation film on the first insulation film, wherein
the first film forming step forms the first insulation film such that the vertical groove has an opening on a first surface side, and
the second film forming step forms the second insulation film across an upper part of the opening of the vertical groove.

11. The manufacturing method according to claim 10, wherein
the second film forming step forms the second insulation film after resist patterning is performed for a target that is the upper part of the opening.

12. The manufacturing method according to claim 10, wherein
the first film forming step forms the first insulation film by atomic layer deposition, and
the second film forming step forms the second insulation film by chemical vapor deposition.

13. The manufacturing method according to claim 10, wherein
the first film forming step forms the first insulation film by atomic layer deposition, and
the second film forming step forms the second insulation film by atomic layer deposition that has a higher film forming temperature than a film forming temperature of the first insulation film.

14. A sensor device comprising:
a semiconductor substrate that includes a plurality of photoelectric conversion elements arranged for each pixel and a pixel separation portion having a trench formed between pixels to separate the pixels, wherein
an insulation film is formed at an outermost peripheral portion of the trench,
a metal film is formed inside the insulation film, and
a similar heat expansion material that has a heat expansion characteristic similar to a heat expansion characteristic of a material constituting the semiconductor substrate is embedded inside the metal film.

15. The sensor device according to claim 14, wherein
the semiconductor substrate is a silicon substrate, and
the similar heat expansion material is silicon.

16. The sensor device according to claim 15, wherein
the similar heat expansion material is polysilicon or amorphous silicon.

17. The sensor device according to claim 14, wherein
the similar heat expansion material is a material to which a conductive material is added.

18. A sensor device comprising:
a semiconductor substrate that includes a plurality of photoelectric conversion elements arranged for each pixel and a pixel separation portion having a trench formed between pixels to separate the pixels;
an insulation film formed on a first surface that is one of two surfaces crossing a thickness direction of the semiconductor substrate at right angles and that corresponds to a surface where the trench is engraved and on an outermost peripheral portion of the trench;
a wetting film formed on the insulation film; and
a metal film formed on the wetting film, wherein
the wetting film becomes amorphous or microcrystalline on the insulation film in the trench and has highly oriented crystals on the insulation film outside the trench.

19. The sensor device according to claim 18, wherein
the wetting film includes TiAl.

20. The sensor device according to claim 18, wherein
the metal film includes Al.
